(19) United States
(12) Patent Application Publication
(10) Pub. No.: US 2020/0216709 A1
(43) Pub. Date: Jul. 9, 2020

(54) COMPOSITION FOR FORMING UNDERLAYER FILM FOR IMPRINTS, KIT, CURABLE COMPOSITION FOR IMPRINTS, LAMINATE, METHOD FOR PRODUCING LAMINATE, METHOD FOR PRODUCING CURED PRODUCT PATTERN, AND METHOD FOR PRODUCING CIRCUIT BOARD

(71) Applicant: FUJIFILM Corporation, Tokyo (JP)

(72) Inventors: Naoya SHIMOJU, Haibara-gun (JP); Yuichiro GOTO, Haibara-gun (JP)

(73) Assignee: FUJIFILM Corporation, Tokyo (JP)

(21) Appl. No.: 16/826,488

(22) Filed: Mar. 23, 2020

Related U.S. Application Data
(63) Continuation of application No. PCT/JP2018/035139, filed on Sep. 21, 2018.

(30) Foreign Application Priority Data
Sep. 26, 2017 (JP) 2017-184854

(51) Int. Cl. C09D 135/02; G03F 7/00; H05K 3/00

(52) U.S. Cl. CPC C09D 135/02; H05K 3/0014; G03F 7/0002

(57) ABSTRACT

There are provided a composition for forming an underlayer film for imprints which imparts excellent uniformity in thickness of a film to be formed, has excellent wettability with respect to a curable composition for imprints, and imparts stability in a film to be formed; a kit; a curable composition for imprints; a laminate; a method for producing a laminate; a method for producing a cured product pattern; and a method for producing a circuit board. A composition for forming an underlayer film for imprints includes a polyfunctional (meth)acrylate that includes at least one aromatic ring or aromatic heterocyclic ring and has a viscosity of 11 to 600 mPa·s at 23° C. and a molecular weight of 200 or more, and a solvent.

### CROSS-REFERENCE TO RELATED APPLICATIONS

This application is a Continuation of PCT International Application No. PCT/JP2018/035139 filed on Sep. 21, 2018, which claims priority under 35 U.S.C. § 119(a) to Japanese Patent Application No. 2017-184854 filed on Sep. 26, 2017. Each of the above application(s) is hereby expressly incorporated by reference, in its entirety, into the present application.

### BACKGROUND OF THE INVENTION

### 1. Field of the Invention

The present invention relates to a composition for forming an underlayer film for imprints, a kit, a curable composition for imprints, a laminate, a method for producing a laminate, a method for producing a cured product pattern, and a method for producing a circuit board.

### 2. Description of the Related Art

Imprinting is a technique advanced from an embossing technique well known in the art of optical disc production, which includes pressing a mold prototype with a concave-convex pattern formed on its surface (this is generally referred to as “mold”, “stamper”, “template”, or the like) against a resist to thereby accurately transfer a fine pattern onto the resist through mechanical deformation of the resist. In this technique, in a case where a mold is prepared once, microstructures such as nanostructures can then be easily and repeatedly molded. Therefore, imprinting is a nanofabrication technique that is economical and has few harmful wastes and discharges. Accordingly, in recent years, it has been anticipated that imprinting will be applied to various technical fields.

Imprinting is a method of transferring a fine pattern onto a photo-cured product, by allowing a curable composition to photo-cure under light irradiation through a light-transmissive mold or a light-transmissive substrate, and then separating the mold. This method is applicable to the field of high-precision processing for forming ultrafine patterns such as fabrication of semiconductor integrated circuits, since the imprinting may be implemented at room temperature. In recent years, new trends in development of nano-casting based on a combination of advantages of both, and reversal imprinting capable of creating a three-dimensional laminated structure have been reported.

Such imprinting is used for a purpose of processing a substrate by a method such as etching using a formed pattern as a mask. By virtue of high precision alignment and a high degree of integration, such a technique can replace a conventional lithographic technique in fabrication of high-density semiconductor integrated circuits, fabrication of transistors in liquid crystal displays, and magnetic processing for next-generation hard disks referred to as patterned media. Efforts to use imprinting practically in these applications have recently become active.

On the other hand, with progress of activities in imprinting, attention has been paid to adhesiveness between the substrate and the curable composition for imprints. In imprinting, the curable composition for imprints is applied to a surface of the substrate, the curable composition for imprints is cured by light irradiation in a state where a mold is brought into contact with a surface of the curable composition for imprints, and thereafter, the mold is released. In the step of releasing the mold, a cured product may peel from the substrate and adheres to the mold. This is thought to be because there is a region in which adhesiveness between the substrate and the cured product is lower than adhesiveness between the mold and the cured product. To solve this problem, use of an adhesion film for imprints using an adhesive composition for imprints that improves the adhesiveness between the substrate and the cured product has been studied (for example, JP2016-028419A). In addition, in a case where the curable composition for imprints is applied by an ink jet (IJ) method, a technique for improving the wet spreading of ink jet liquid droplets has been studied (for example, JP2017-055108A).

### SUMMARY OF THE INVENTION

The inventors of the present invention have paid attention to a technique using a film (an underlayer film) formed of a composition for forming an underlayer film for imprints between a curable composition for imprints and a substrate. The technique is to thereby improve adhesiveness between the curable composition for imprints and the substrate, and to improve releasability of a mold. Specifically, as shown in FIG. 2, an underlayer film 21 is formed by applying a composition for forming an underlayer film for imprints to a substrate. Liquid droplets of a curable composition for imprints 22 are added dropwise on a surface of the film at an appropriate distance. By bringing a mold into contact therewith, the liquid droplets are spread on the underlayer film 21, and the curable composition for imprint 22 becomes a film-like shape. Thereafter, the curable composition for imprint (a pattern forming layer) is cured, and thereby an imprint layer having a desired pattern is obtained. An object of the present invention is to improve a composition for forming an underlayer film for imprints used in such an aspect, and a technique using the composition.

Specifically, an object of the present invention is to provide a composition for forming an underlayer film for imprints which imparts excellent uniformity in thickness of a film to be formed, has excellent wettability with respect to a curable composition for imprints, and imparts stability in a film to be formed; a kit; a curable composition for imprints; a laminate; a method for producing a laminate; a method for producing a cured product pattern; and a method for producing a circuit board.

The foregoing problem has been solved by the following means <1>, preferably <2> to <17>.

<1> A composition for forming an underlayer film for imprints, comprising: a polyfunctional (meth)acrylate that includes at least one aromatic ring or aromatic heterocyclic ring; and a solvent, in which a viscosity of the polyfunctional (meth)acrylate at 23° C. is 11 to 600 mPa·s, and a molecular weight of the polyfunctional (meth)acrylate is 200 or more.

<2> The composition for forming an underlayer film for imprints according to <1>, in which the at least one ring included in the polyfunctional (meth)acrylate satisfies at least one of the following conditions (a) to (d):

(a) the at least one ring includes at least one 5-membered ring or 6-membered ring;

(b) the at least one ring includes a heterocyclic ring having at least one of a nitrogen atom, an oxygen atom, or a sulfur atom as a hetero atom;

(c) the at least one ring includes a fused ring; and

(d) the at least one ring includes two or more rings selected from aromatic rings and aromatic heterocyclic rings.

<3> The composition for forming an underlayer film for imprints according to <1> or <2>, in which a boiling point of the polyfunctional (meth)acrylate is 370° C. or higher.

<4> The composition for forming an underlayer film for imprints according to any one of <1> to <3>, in which an Ohnishi parameter of the polyfunctional (meth)acrylate is 2.0 to 4.5; where, the Ohnishi parameter is (a sum of the number of carbon atoms, hydrogen atoms, and oxygen atoms)/(the number of carbon atoms−the number of oxygen atoms) for atoms constituting each compound.

<5> The composition for forming an underlayer film for imprints according to any one of <1> to <4>, in which the polyfunctional (meth)acrylate is represented by Formula (1).

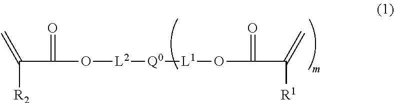

In the formula, Q⁰ represents at least one aromatic-ring-containing group or aromatic-heterocyclic-ring-containing group, R¹ and R² each independently represent a hydrogen atom or a methyl group, L¹ and L² each independently represent a single bond or a linking group, and m represents an integer of 1 to 4.

<6> The composition for forming an underlayer film for imprints according to any one of <1> to <5>, in which a content of the polyfunctional (meth)acrylate is 0.01% by mass to 1.0% by mass.

<7> A kit comprising: the composition for forming an underlayer film for imprints according to any one of <1> to <6>; and a curable composition for imprints.

<8> The kit according to <7>, in which the curable composition for imprints includes a polyfunctional (meth)acrylate, and the polyfunctional (meth)acrylate in the curable composition for imprints includes at least one aromatic ring or aromatic heterocyclic ring.

<9> The kit according to <7> or <8>, in which an absolute value of a difference between a viscosity of the polyfunctional (meth)acrylate used in the composition for forming an underlayer film for imprints at 23° C. and a viscosity of the curable composition for imprints at 23° C. is 500 mPa·s or less.

<10> A composition for forming an underlayer film for imprints, which is included in the kit according to any one of <7> to <9>.

<11> A curable composition for imprints, which is used for the kit according to any one of <7> to <9>.

<12> A laminate formed from the kit according to any one of <7> to <9>, the laminate comprising:

an underlayer film formed from the composition for forming an underlayer film for imprints; and

a pattern forming layer formed from the curable composition for imprints and positioned on a surface of the underlayer film.

<13> A method for producing a laminate using the kit according to any one of <7> to <9>, the method comprising:

a step of applying a curable composition for imprints on a surface of an underlayer film formed from a composition for forming an underlayer film for imprints.

<14> The method for producing a laminate according to <13>, in which the curable composition for imprints is applied on the surface of the underlayer film by an ink jet method.

<15> The method for producing a laminate according to <13> or <14>, further comprising:

a step of applying the composition for forming an underlayer film for imprints in a layer form on a substrate;

and a step of heating the composition for forming an underlayer film for imprints applied in a layer form at 40° C. to 100° C.

<16> A method for producing a cured product pattern, using the kit according to any one of <7> to <9>, the method comprising:

an underlayer film forming step of applying a composition for forming an underlayer film for imprints on a substrate to form an underlayer film;

an applying step of applying a curable composition for imprints on a surface of the underlayer film;

a mold contact step of bringing the curable composition for imprints into contact with a mold having a pattern for transferring a pattern shape;

a light irradiation step of irradiating the curable composition for imprints with light to form a cured product; and

a mold release step of separating the cured product and the mold from each other.

<17> A method for producing a circuit board, comprising:

a step of obtaining a cured product pattern by the production method according to <16>.

According to the present invention, it is possible to provide a composition for forming an underlayer film for imprints which imparts excellent uniformity in thickness of a film to be formed, has excellent wettability with respect to a curable composition for imprints, and imparts stability in a film to be formed; a kit; a curable composition for imprints; a laminate; a method for producing a laminate; a method for producing a cured product pattern; and a method for producing a circuit board.

### BRIEF DESCRIPTION OF THE DRAWINGS

FIG. 1 shows an example of a production process in a case where a cured product pattern is formed and the obtained cured product pattern is used for processing a substrate by etching.

FIG. 2 is a schematic view showing a state of wet spreading of a curable composition for imprints in a case where the curable composition for imprints is applied on a surface of an underlayer film by an ink jet method.

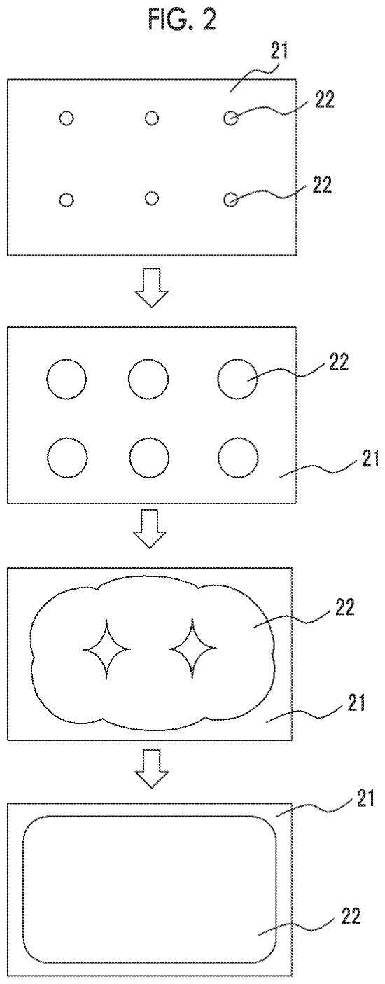

### DESCRIPTION OF THE PREFERRED EMBODIMENTS

Hereinafter, the contents of the present invention will be described in detail. In the present specification, the numerical ranges shown with “to” means ranges including the numerical values indicated before and after “to” as a lower limit value and an upper limit value, respectively.

In the present specification, the term “(meth)acrylate” represents acrylate and methacrylate.

In the present specification, the term “imprint” preferably refers to pattern transfer in a size of 1 nm to 10 mm and more preferably pattern transfer in a size of approximately 10 nm to 100 μm (nanoimprint).

In the description of a group (atomic group) in the present specification, the description with no indication of “substituted” or “unsubstituted” includes both a group (atomic group) having a substituent and a group (atomic group) not having a substituent. For example, the term “alkyl group” includes not only an alkyl group not having a substituent (unsubstituted alkyl group) but also an alkyl group having a substituent (substituted alkyl group).

A temperature in the present invention is 23° C. unless otherwise specified.

In the present specification, the term “light” includes not only light in wavelength regions of ultraviolet, near ultraviolet, far ultraviolet, visible light and infrared, and electromagnetic waves, but also radiation rays. The radiation rays include microwaves, electron beams, extreme ultraviolet (EUV), and X-rays. Laser light such as a 248 nm excimer laser, a 193 nm excimer laser, and a 172 nm excimer laser can also be used. These sorts of light may be monochromatic light (single wavelength light) that has passed through an optical filter, or may be light that has a plurality of different wavelengths (complex light).

Unless otherwise specified, the weight-average molecular weight (Mw) in the present invention refers to a value as measured by gel permeation chromatography (GPC).

The boiling point in the present invention refers to a boiling point at 1 atmosphere (1 atm=1013.25 hPa).

### Composition for Forming Underlayer Film for Imprints

A composition for forming an underlayer film for imprints of the embodiment of the present invention includes polyfunctional (meth)acrylate that includes at least one aromatic ring or aromatic heterocyclic ring; and a solvent, in which a viscosity of the polyfunctional (meth)acrylate at 23° C. is 11 to 600 mPa·s, and a molecular weight of the polyfunctional (meth)acrylate is 200 or more. By adopting such a configuration, it is possible to obtain a composition for forming an underlayer film for imprints which imparts excellent uniformity in thickness of a film to be formed, has excellent wettability with respect to a curable composition for imprints, and imparts stability in a film to be formed.

In particular, even in a case where an underlayer film is thin, a film having a uniform thickness can be formed. In addition, the composition can also be said to be a composition for forming an underlayer film for imprints which has excellent temporal stability.

### Polyfunctional (meth)acrylate

In the present invention, the polyfunctional (meth)acrylate used in the composition for forming an underlayer film for imprints has at least one aromatic ring or aromatic heterocyclic ring, and more preferably has at least an aromatic ring. As one embodiment of the present invention, an aspect in which polyfunctional (meth)acrylate has an aromatic ring and does not have an aromatic heterocyclic ring is exemplified.

The aromatic ring is preferably a hydrocarbon aromatic ring having 6 to 22 carbon atoms (more preferably 6 to 18 carbon atoms, and even more preferably 6 to 10 carbon atoms). The aromatic ring may be a monocyclic ring or a fused ring, and is preferably a monocyclic ring. Specific examples of aromatic rings include a benzene ring, a naphthalene ring, an anthracene ring, a phenanthrene ring, a phenalene ring, a fluorene ring, an acenaphthylene ring, a biphenylene ring, an indene ring, an indane ring, a triphenylene ring, a pyrene ring, a chrysene ring, a perylene ring, and the like (these examples will be referred to as a ring Cy). The aromatic heterocyclic ring is preferably an aromatic heterocyclic ring having 1 to 12 carbon atoms (more preferably 1 to 6 carbon atoms and even more preferably 1 to 5 carbon atoms). The aromatic heterocyclic ring may be a monocyclic ring or a fused ring, and is preferably a monocyclic ring. A hetero atom that an aromatic heterocyclic ring has is not particularly limited, but it is preferably an oxygen atom, a nitrogen atom, a sulfur atom, or a combination thereof. Specific examples of aromatic heterocyclic rings include a thiophene ring, a furan ring, a pyrrole ring, an imidazole ring, a pyrazole ring, a triazole ring, a tetrazole ring, a thiazole ring, an oxazole ring, a pyridine ring, a pyrazine ring, a pyrimidine ring, a pyridazine ring, an isoindole ring, an indole ring, an indazole ring, a purine ring, a quinolidine ring, an isoquinoline ring, a quinoline ring, a phthalazine ring, a naphthyridine ring, a quinoxaline ring, a quinazoline ring, a cinnoline ring, a carbazole ring, an acridine ring, a phenazine ring, a phenothiazine ring, a phenoxazine ring (these examples will be referred to as a ring hCy).

At least one ring included in the polyfunctional (meth)acrylate preferably satisfies at least one of the following conditions (a) to (d):

(a) the at least one ring includes at least one 5-membered ring or 6-membered ring;

(b) the at least one ring includes a heterocyclic ring having at least one of a nitrogen atom, an oxygen atom, or a sulfur atom as a hetero atom;

(c) the at least one ring includes a fused ring; and

(d) the at least one ring includes two or more rings selected from aromatic rings and aromatic heterocyclic rings.

In addition, as the polyfunctional (meth)acrylate used in the present invention, an aspect is exemplified in which hetero atoms other than the hetero atoms included in the above-mentioned aromatic heterocyclic rings are not included. As the polyfunctional (meth)acrylate used in the present invention, an aspect is exemplified in which a ring is constituted only from a carbon atom, an oxygen atom, and a hydrogen atom.

The polyfunctional (meth)acrylate is preferably represented by Formula (1).

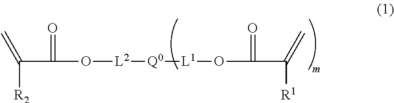

In the formula, Q⁰ represents at least one aromatic-ring-containing group or aromatic-heterocyclic-ring-containing group, R¹ and R² each independently represent a hydrogen atom or a methyl group, L¹ and L² each independently represent a single bond or a linking group, and m represents an integer of 1 to 4. m is preferably 1 to 3 and is more preferably 1 or 2. In a case where L¹ and L² are linking groups, there are examples of linking groups L to be described later. In a case where L¹ and L² are linking groups that may have a substituent, they may have a substituent T to be described later. Q⁰ in the formula may be bonded to L¹ or L² via or without a linking group L to form a ring. For example, in a case where Q⁰ is a benzene ring and L² is a methylene group, L² may be bonded to the benzene ring of Q⁰ via a phenylene group to form a ring, thereby forming a fluorene structure (an exemplary compound B-20 to be described later). Alternatively, Q⁰ may be a phenylethyl group, L² may be a methylene group, and the ortho position of the benzene ring of Q⁰ and the methylene group of L² may be bonded to form an indane structure (for example, an exemplary compound B-12 to be described later).

Q⁰ is preferably an aromatic-ring-containing group and an aromatic-heterocyclic-ring-containing group represented by Formula (1-1) or (1-2). However, in Formula (1-2), m in Formula (1) is 1.

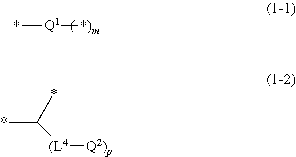

Q¹ is an (m+1)-valent aromatic-ring-containing group or aromatic-heterocyclic-ring-containing group. Preferable examples of aromatic rings and aromatic heterocyclic rings are the same as the above-mentioned ring Cy or ring hCy. The symbol * represents a bonding position. Q¹ may be bonded to L¹ or L² of Formula (1) via or without a linking group L to form a ring. Q¹ may have one or two or more substituents T within a range where the effects of the present invention are exhibited. In a case where there are a plurality of substituents T, they may be bonded to each other, bonded to L¹ or L² of Formula (1), or bonded to Q¹ to form a ring. In a case where there are a plurality of substituents T, they may be the same as or different from each other. m has the same meaning as defined in Formula 1.

Q² is an (m+1)-valent aromatic-ring-containing group or aromatic-heterocyclic-ring-containing group. Preferable examples of aromatic rings and aromatic heterocyclic rings are the same as the above-mentioned ring Cy or ring hCy. The symbol * represents a bonding position. p is 1 or 2. L⁴ is a single bond or a linking group. Examples of linking groups include a linking group L to be described later. Among these, L⁴ is preferably a single bond, a methylene group, an ethylene group, a 2,2-propanediyl group, —O—, —S—, —SO₂—, —CO—, or —COO—. Q² may be bonded to L⁴, or L¹ or L² of Formula (1) to form a ring. In a case where there are a plurality of L⁴-Q²'s, they may be the same as or different from each other. In a case where there are a plurality of L⁴-Q²'s, they may be bonded to each other via or without a linking group L to form a ring. Q² may have one or two or more substituents T within a range where the effects of the present invention are exhibited. In a case where there are a plurality of substituents T, they may be bonded to each other, bonded to L⁴ in the formula, bonded to Q¹, or L¹ or L² of Formula (1), or bonded to Q² to form a ring. In a case where there are a plurality of substituents T, they may be the same as or different from each other.

Q¹ is preferably a group represented by any of Formulae (Q1-1) to (Q1-4).

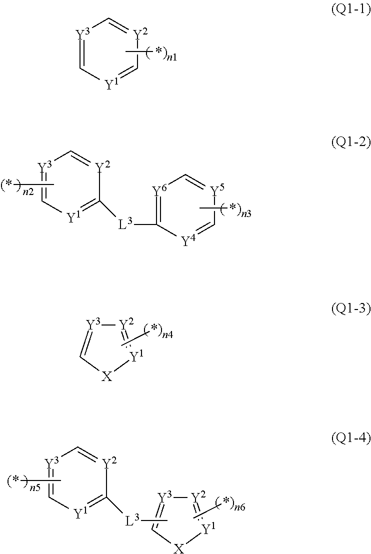

Y¹ to Y⁶ each independently represent a methine group or a nitrogen atom. X represents NR^{N}, an oxygen atom, or a sulfur atom. R^{N} has the same meaning as defined below. n1 is an integer of m+1. n2 and n3 are integers of 1 or more. Here, n2+n3 is an integer of m+1. n4 is an integer of m+1. n5 and n6 are integers of 1 or more. Here, n5+n6 is an integer of m+1. L³ is a single bond or a linking group. The linking group is preferably the following linking group L. Among these, L³ is preferably a single bond, a methylene group, an ethylene group, a 2,2-propanediyl group, —O—, —S—, —SO₂—, —CO—, or —COO—. In a case where L³ is a linking group that may have a substituent, it may have a substituent T within a range where the effects of the present invention are exhibited. For example, in a case where L³ is an alkylene group, an aspect in which a fluorine atom is substituted is exemplified as a preferable aspect. The symbol * represents a bonding position. A bonding position represented may extend from a carbon atom in the formula, may extend from a carbon atom of a methine group in a case where Y¹ to Y⁶ are methine groups, or may extend from a nitrogen atom or a group of R^{N} in a case where X is NR^{N}. L³ may be bonded to an aromatic ring or an aromatic heterocyclic ring in the formula via or without a linking group L to form a ring. Aromatic rings or aromatic heterocyclic rings in Formulae (Q1-1) to (Q1-4) may have a substituent T to be described below within a range where the effects of the present invention are exhibited. The substituent T may be substituted with a carbon atom in the formula, a carbon atom of a methine group in a case where Y¹ to Y³ are methine groups, or a nitrogen atom or R^{N} in a case where X is NR^{N}. Among these, as the substituent T in this case, an aryl group (particularly a phenyl group), an aralkyl group (particularly a benzyl group), a (meth)acryloyloxy group, and a (meth)acryloyloxyalkyl group are preferable. In a case where there are a plurality of substituents T, they may be bonded to each other, or bonded to a linking group of L¹ or L² in Formula (1), bonded to a linking group of L³ in Formula (Q1-2) or (Q1-4), or bonded to an aromatic ring or an aromatic heterocyclic ring in the formula to form a ring. For example, Q¹ may be a benzene ring having a hydroxyl group and a propyl group, and both may be bonded to form a dihydrobenzofuran ring (an exemplary compound B-4). In a case where there are a plurality of substituents T, they may be the same as or different from each other. Aromatic rings or aromatic heterocyclic rings in Formulae (Q1-1) to (Q1-4) may be bonded to L¹ or L² in Formula (1) to form a ring. The left and right aromatic rings or aromatic heterocyclic rings in Formulae (Q1-2) and (Q1-4) may be bonded to each other via or without a linking group L to form a ring.

Q² is preferably a group represented by any of Formulae (Q2-1) and (Q2-2).

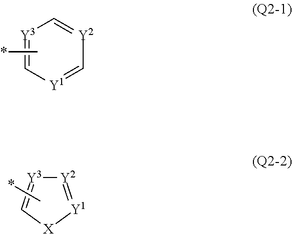

X and Y¹ to Y³ are groups having the same meanings as defined in Formulae (Q1-1) to (Q1-4). The symbol * represents a bonding position. A bonding position represented may extend from a carbon atom in the formula, may extend from a carbon atom of a methine group in a case where Y¹ to Y³ are methine groups, or may extend from a nitrogen atom or a group of R^{N} in a case where X is NR^{N}. The group represented by any one of Formulae (Q2-1) and (Q2-2) may have a substituent T to be described below within a range where the effects of the present invention are exhibited. The substituent T may be substituted with a carbon atom in the formula, a carbon atom of a methine group in a case where Y¹ to Y³ are methine groups, or a nitrogen atom or a group of R^{N} in a case where X is NR^{N}. Among these, as the substituent T in this case, an aryl group (particularly a phenyl group), an aralkyl group (particularly a benzyl group), a (meth)acryloyloxy group, and a (meth)acryloyloxyalkyl group are preferable. In a case where there are a plurality of substituents T, they may be bonded to each other, or bonded to a linking group of L¹ or L³ in Formula (1), bonded to a linking group of L⁴ in Formula (1-2) or a carbon atom to which L⁴ is bonded, or bonded to an aromatic ring or an aromatic heterocyclic ring in the formula to form a ring. In a case where there are a plurality of substituents T, they may be the same as or different from each other. Aromatic rings or aromatic heterocyclic rings in Formulae (Q2-1) and (Q2-2) may be bonded to L⁴ of Formula (1-2) via or without a linking group L, bonded to a carbon atom to which L⁴ is bonded, or bonded to L¹ or L² of Formula (1) to form a ring.

As the linking group L, linking groups according to a linear or branched alkylene group (preferably having 1 to 24 carbon atoms, more preferably having 1 to 12 carbon atoms, and even more preferably having 1 to 6 carbon atoms), an arylene group (preferably having 6 to 22 carbon atoms, more preferably having 6 to 18 carbon atoms, and even more preferably having 6 to 10 carbon atoms), —O—, —S—, —SO₂—, —CO—, —NR^{N}—, and combinations thereof are exemplified. R^{N} represents a hydrogen atom or an alkyl group (preferably having 1 to 12 carbon atoms, more preferably having 1 to 6 carbon atoms, even more preferably having 1 to 3 carbon atoms, and still more preferably a methyl group). An alkylene group may have the following substituent T. For example, the alkylene group may be a fluorinated alkylene group in which an alkylene group has a fluorine atom. The number of atoms included in the linking group L is preferably 1 to 24, is more preferably 1 to 12, and is even more preferably 1 to 6.

Examples of substituent T's include an alkyl group (preferably having 1 to 24 carbon atoms, more preferably having 1 to 12 carbon atoms, and even more preferably having 1 to 6 carbon atoms), a cycloalkyl group (preferably having 3 to 24 carbon atoms, more preferably having 3 to 12 carbon atoms, and even more preferably having 3 to 6 carbon atoms), an aralkyl group (preferably having 7 to 21 carbon atoms, more preferably having 7 to 15 carbon atoms, and even more preferably having 7 to 11 carbon atoms), an alkenyl group (preferably having 2 to 24 carbon atoms, more preferably having 2 to 12 carbon atoms, and even more preferably having 2 to 6 carbon atoms), a cycloalkenyl group (preferably having 3 to 24 carbon atoms, more preferably having 3 to 12 carbon atoms, and even more preferably having 3 to 6 carbon atoms), a hydroxyl group, an amino group (preferably having 0 to 24 carbon atoms, more preferably having 0 to 12 carbon atoms, and even more preferably having 0 to 6 carbon atoms), a thiol group, a carboxyl group, an aryl group (preferably having 6 to 22 carbon atoms, more preferably having 6 to 18 carbon atoms, and even more preferably having 6 to 10 carbon atoms), an acyl group (preferably having 2 to 12 carbon atoms, more preferably having 2 to 6 carbon atoms, and even more preferably having 2 to 3 carbon atoms), an acyloxy group (preferably having 2 to 12 carbon atoms, more preferably having 2 to 6 carbon atoms, and even more preferably having 2 to 3 carbon atoms), an aryloyl group (preferably having 7 to 23 carbon atoms, more preferably laving 7 to 19 carbon atoms, and even more preferably having 7 to 11 carbon atoms), an aryloyloxy group (preferably having 7 to 23 carbon atoms, more preferably having 7 to 19 carbon atoms, and even more preferably having 7 to 11 carbon atoms), a carbamoyl group (preferably having 1 to 12 carbon atoms, more preferably having 1 to 6 carbon atoms, and even more preferably having 1 to 3 carbon atoms), a sulfamoyl group (preferably having 0 to 12 carbon atoms, more preferably having 0 to 6 carbon atoms, and even more preferably having 0 to 3 carbon atoms), a sulfo group, an alkylsulfonyl group (preferably having 1 to 12 carbon atoms, more preferably having 1 to 6 carbon atoms, and even more preferably having 1 to 3 carbon atoms), an arylsulfonyl group (preferably having 6 to 22 carbon atoms, more preferably having 6 to 18 carbon atoms, and even more preferably having 6 to 10 carbon atoms), a heterocyclic group (preferably having 1 to 12 carbon atoms, more preferably having 1 to 8 carbon atoms, and even more preferably having 2 to 5 carbon atoms, and preferably having a 5- or 6-membered ring), a (meth)acryloyl group, a (meth)acryloyloxy group, a (meth)acryloyloxyalkyl group (an alkyl group preferably has 1 to 24 carbon atoms, more preferably has 1 to 12 carbon atoms, and even more preferably has 1 to 6 carbon atoms), halogen atoms (for example, a fluorine atom, a chlorine atom, a bromine atom, and an iodine atom), an oxo group (═O), an imino group (═NR^{N}), an alkylidene group (═C(R^{N})₂), and the like. R^{N} is as defined above. An alkyl moiety and an alkenyl moiety included in each substituent may be linear or branched, or may be linear or cyclic. In a case of a group in which the substituent T may have a substituent, the group may further have a substituent T. For example, an alkyl group may be a halogenated alkyl group, or may be an aminoalkyl group or a carboxyalkyl group. In a case of a group in which a substituent may form salts of a carboxyl group, an amino group, or the like, this group may form salts.

In the composition for forming an underlayer film for imprints of the embodiment of the present invention, the polyfunctional (meth)acrylate has an aromatic ring or on aromatic heterocyclic ring as described above, thereby increasing surface tension, improving wettability with respect to a curable composition for imprints, and achieving an effective molding process. Accordingly, this leads to improvement of characteristics of a pattern forming layer (a layer of a curable composition for imprints). In addition, by also incorporating a compound (particularly polyfunctional (meth)acrylate) having an aromatic ring or an aromatic heterocyclic ring in the curable composition for imprints, interfacial tension between an underlayer film and the curable composition for imprints becomes small, and thereby it becomes possible to form a favorable pattern forming layer having excellent compatibility.

### Viscosity

A viscosity of the polyfunctional (meth)acrylate included in the composition for forming an underlayer film for imprints is 11 mPa·s or more, is preferably 13 mPa·s or more, is more preferably 15 mPa·s or more, is even more preferably 18 mPa·s or more, and is still even more preferably 20 mPa·s or more. The viscosity is 600 mPa·s or less, preferably 500 mPa·s or less, more preferably 400 mPa·s or less, still more preferably 300 mPa·s or less, and even still more preferably 150 mPa·s or less. In a case where the viscosity is within the above range, it is particularly preferable from the viewpoint of suitably controlling uniformity in film thickness. In the present specification, unless otherwise specified, the viscosity is a value at 23° C. measured by a measurement method described in the Examples to be described later.

An absolute value (Δη)=(|η2−η1|) of a difference between a viscosity (η1) of the polyfunctional (meth)acrylate used in the composition for forming an underlayer film for imprints and a viscosity (η2) of the curable composition for imprints is preferably 500 mPa·s or less, is more preferably 400 mPa·s or less, is even more preferably 300 mPa·s or less, and is still even more preferably 150 mPa·s or less. In a case where the difference Δη of these viscosities is within the above range, diffusion uniformity between the composition for forming an underlayer film for imprints and the curable composition for imprints tends to be further improved.

In a case of using multiple polyfunctional (meth)acrylates, a viscosity is a viscosity (η1) of a liquid into which each polyfunctional (meth)acrylate is mixed at a proportion of each polyfunctional (meth)acrylate contained in the composition.

### Molecular Weight

A molecular weight of the polyfunctional (meth)acrylate used for the composition for forming an underlayer film for imprints is 200 or more, is preferably 300 or more, and is more preferably 400 or more. The upper limit thereof is not particularly limited, but it is 1500 or less from the viewpoint of practicality. In a case where the molecular weight is within the above range, it is preferable from the viewpoint that it is possible to suitability achieve stability of a film.

### Boiling Point

A boiling point of the polyfunctional (meth)acrylate used for the composition for forming an underlayer film for imprints is preferably 300° C. or higher, is more preferably 330° C. or higher, is even more preferably 350° C. or higher, is still even more preferably 370° C. or higher, and yet more preferably 400° C. or higher. The upper limit of the boding point is not particularly defined, but can be, for example, 1500° C. or lower, further 1,000° C. or lower, and particularly 800° C. or lower. In a case where the boiling point of the polyfunctional (meth)acrylate is within the above range, volatility can be controlled within a suitable range, which contributes to formation of a uniform and stable underlayer film. In addition, in a case of using multiple polyfunctional (meth)acrylates, the lowest value is adopted as a boiling point of polyfunctional (meth)acrylate among boiling points of each polyfunctional (meth)acrylate.

### Surface Tension

The surface tension (γUL) of the non-volatile component in the composition for forming an underlayer film for imprints at 23° C. is preferably 30 mN/m or more, is more preferably 33 mN/m or more, is even more preferably 35 mN/m or more, and is still even more preferably 38 mN/m or more. The upper limit of the surface tension is not specifically defined, but it is, for example, 50 mN/m or less. In a case where the surface tension γUL is within the above range, a sufficient difference in surface tension from the curable composition for imprints can be secured, and thereby more favorable residual film uniformity can be achieved. The surface tension is measured according to a method described in the Examples to be described later. In the present specification, the surface tension is a value at 23° C. unless otherwise specified.

### Ohnishi Parameter

An Onishi parameter of the polyfunctional (meth)acrylate used in the composition for forming an underlayer film for imprints is preferably 2.0 or more, is more preferably 2.5 or more, and is even more preferably 3.0 or more. In a case where the Onishi parameter is the above-mentioned lower limit value or more, etching process resistance tends to be further improved. The upper limit thereof is preferably 5.0 or less, is more preferably 4.8 or less, and is even more preferably 4.5 or less. In a case where the Onishi parameter is the above-mentioned upper limit value or less, variations in dry etching resistance can be reduced even in a case where the polyfunctional (meth)acrylate is mixed with a curable composition. A method of calculating an Ohnishi parameter is performed according to a method described in the Examples to be described later.

In a case where a plurality of polyfunctional (meth)acrylates are used in the composition for forming an underlayer film for imprints, it does not forbid inclusion of some polyfunctional (meth)acrylates having a molecular weight, a boiling point, a surface tension, and an Onishi parameter which are beyond the ranges of those specified in the present invention within the range where the effects of the present invention are exhibited. In the present invention, at least one, preferably at least two, more preferably at least three, and more preferably all of the molecular weight, boiling point, surface tension, and Onishi parameter are satisfied.

Hereinafter, specific examples of the polyfunctional (meth)acrylate used in the composition for forming an underlayer film for imprints in the embodiment of the present invention will be shown, but the present invention is not interpreted as being limited thereto. In specifications of compounds shown in Table 1, compounds used in the Comparative Examples to be described later are shown together.

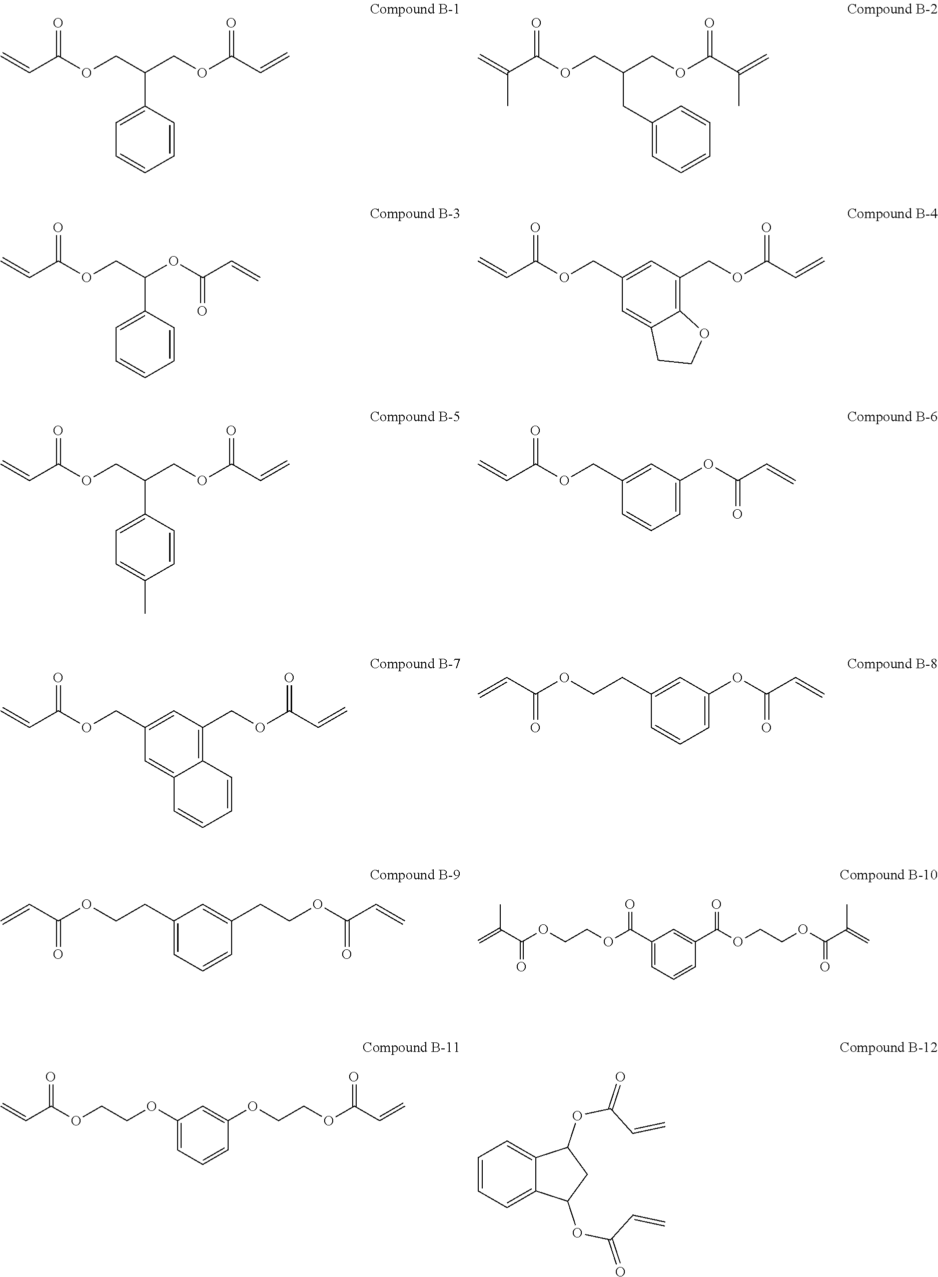

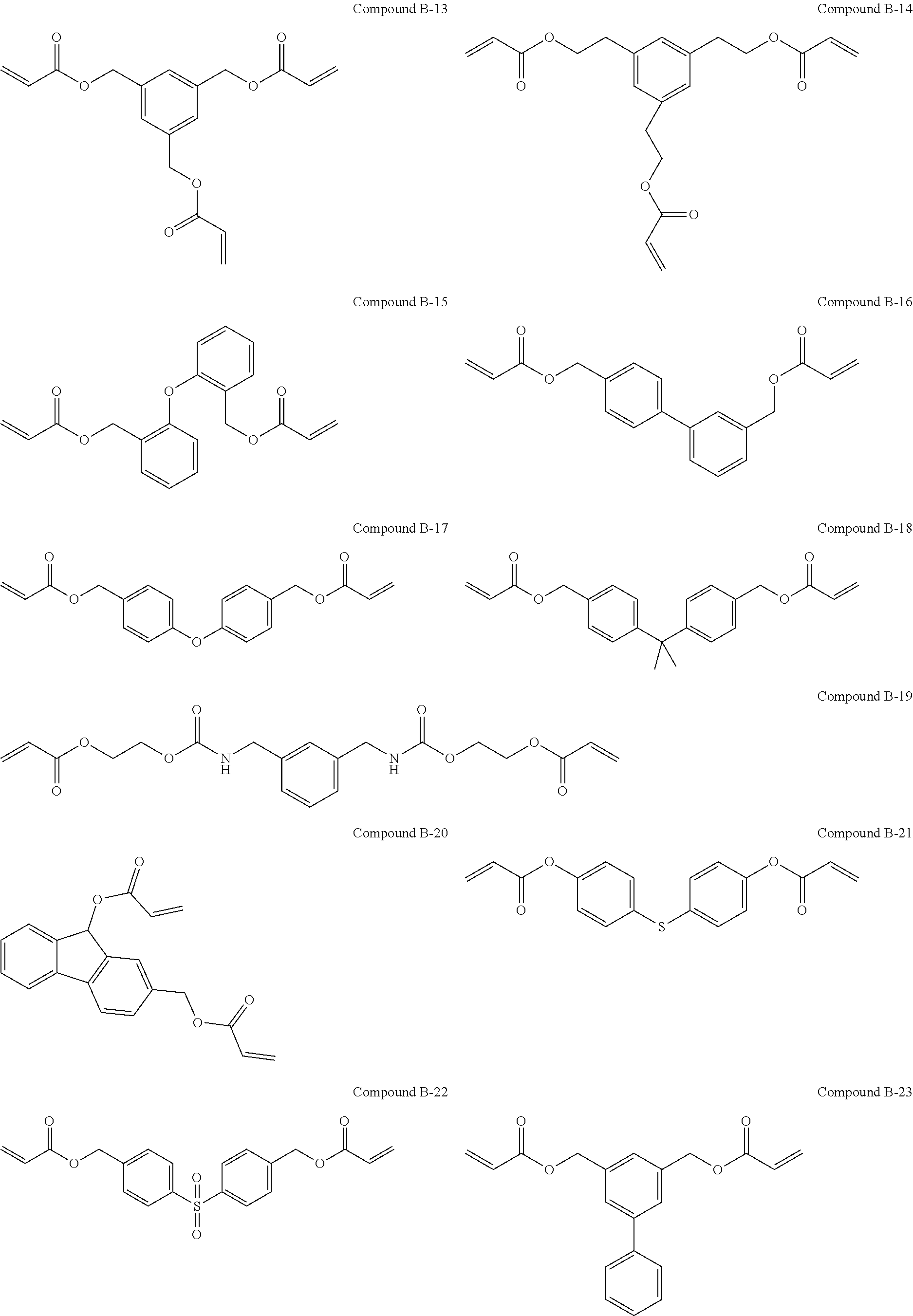

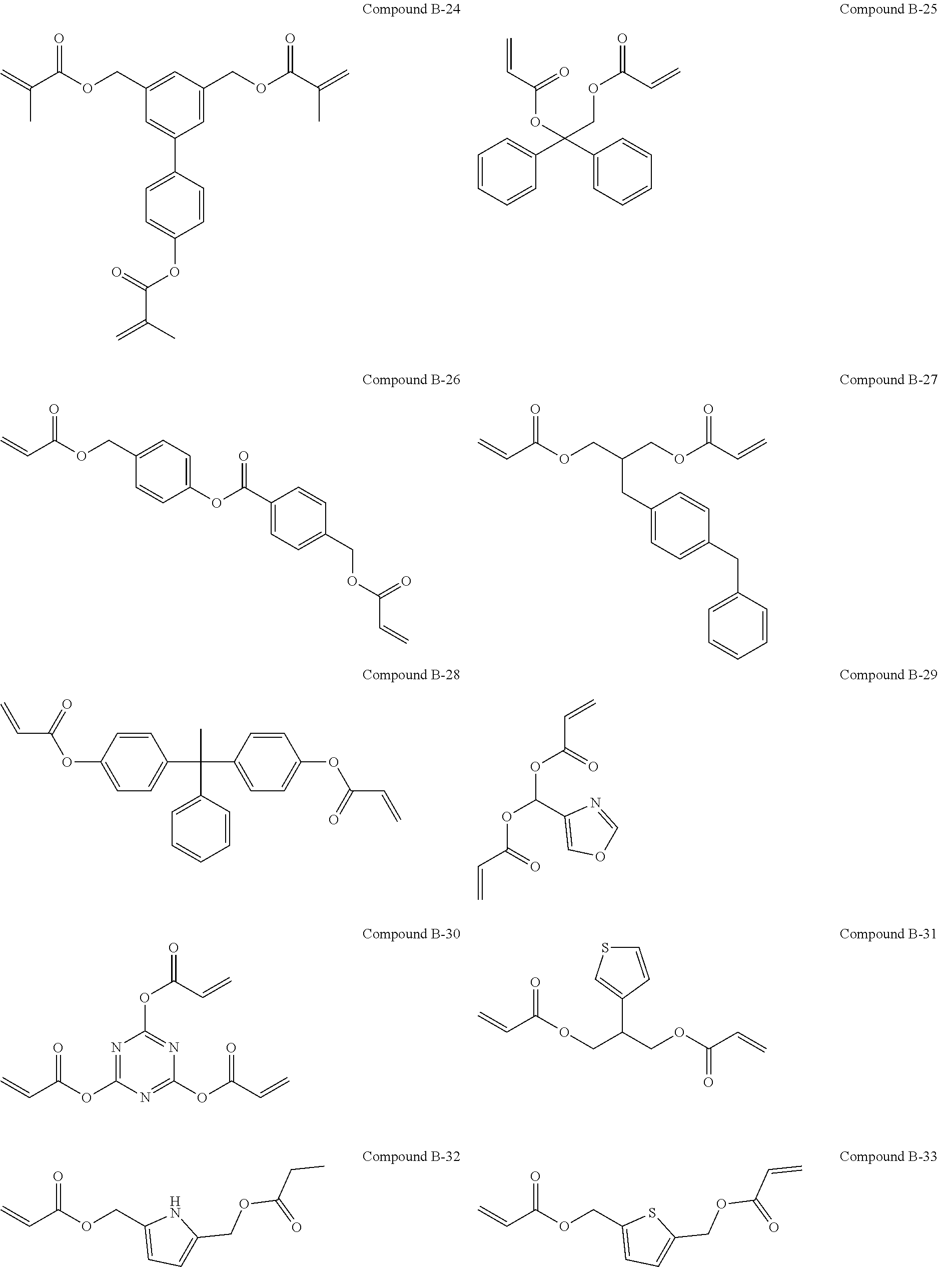

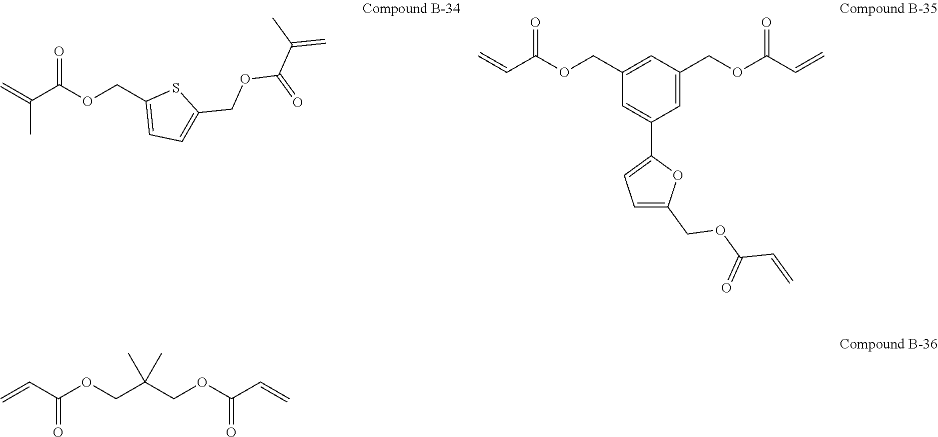 [SMILES: C=C(C)C(=O)OCc1ccc(COC(=O)C(=C)C)s1 ; C=CC(=O)OCc1cc(COC(=O)C=C)cc(-c2ccc(COC(=O)C=C)o2)c1 ; C=CC(=O)OCC(C)(C)COC(=O)C=C]

TABLE 1

| | | | | | | Viscosity |
|---|---|---|---|---|---|---|
| | | | Boiling | Surface | | difference |
| | Molecular | Viscosity | point | tension | | with curable |
| | weight | (25° C.) | (1013.25 hPa) | (25° C.) | Ohnishi | composition |
| Compound | [g/mol] | [mPa · s] | [° C.] | [mN/m] | parameter | (V-2) |
| B-1 | 260.29 | 27.8 | 405.7 | 38.2 | 3.18 | 21.0 |
| B-2 | 302.37 | 29.2 | 474.1 | 36.5 | 3.17 | 22.4 |
| B-3 | 246.26 | 28.1 | 382.8 | 37.5 | 3.20 | 21.3 |
| B-4 | 288.30 | 35.2 | 482.3 | 39.9 | 3.36 | 28.4 |
| B-5 | 260.29 | 13.8 | 416.1 | 38.5 | 3.18 | 7.0 |
| B-6 | 232 24 | 12.1 | 365.4 | 39.0 | 3.22 | 5.3 |
| B-7 | 296.32 | 36.5 | 503.7 | 40.2 | 2.71 | 29.7 |
| B-8 | 246.26 | 22.3 | 388.2 | 39.1 | 3.20 | 15.5 |
| B-9 | 274.32 | 24.6 | 434.0 | 38.5 | 3.17 | 17.8 |
| B-10 | 390.39 | 35.6 | 641.7 | 40.2 | 4.40 | 28.8 |
| B-11 | 306.31 | 36.5 | 478.8 | 40.1 | 4.00 | 29.7 |
| B-12 | 258.27 | 110.2 | 413.2 | 38.7 | 3.00 | 103.4 |
| B-13 | 330.34 | 46.0 | 539.6 | 40.3 | 3.50 | 39.2 |
| B-14 | 372.42 | 80.6 | 608 3 | 38.6 | 3.40 | 73.8 |
| B-15 | 338.36 | 110.9 | 579.6 | 40.8 | 2.87 | 104.1 |
| B-16 | 322.36 | 120.6 | 557.2 | 41.1 | 2.63 | 113.8 |
| B-17 | 338.36 | 165.0 | 579.6 | 41.3 | 2.87 | 158.2 |
| B-18 | 364.44 | 250.6 | 622.6 | 40.8 | 2.68 | 243.8 |
| B-19 | 420.42 | 220.2 | 742.3 | 43.5 | 4.33 | 213.4 |
| B-20 | 320.34 | 452.2 | 560.4 | 41.0 | 2.50 | 445 4 |
| B-21 | 326.37 | 166.6 | 580.2 | 40.8 | 2.57 | 159.8 |
| B-22 | 386.42 | 288.6 | 729.9 | 41.6 | 3.14 | 281.8 |
| B-23 | 322.36 | 300.9 | 557.2 | 40.5 | 2.63 | 294.1 |
| B-24 | 434.49 | 368.8 | 754 0 | 41.3 | 2.88 | 362.0 |
| B-25 | 322.36 | 168.5 | 544.0 | 41.0 | 2.63 | 161.7 |
| B-26 | 366.37 | 226.7 | 638.3 | 39.9 | 3.00 | 219.9 |
| B-27 | 364.44 | 180.1 | 620.4 | 38.6 | 2.68 | 173.3 |
| B-28 | 398.46 | 550.6 | 717.9 | 41.2 | 2.36 | 543.8 |
| B-29 | 223.18 | 140.3 | 368.5 | 39.9 | 4.80 | 133.5 |
| B-30 | 291.22 | 440.2 | 563.5 | 40.7 | 4.50 | 433.4 |
| B-31 | 266.31 | 27.1 | 404.3 | 38.9 | 3.44 | 20.3 |
| B-32 | 235.24 | 90.5 | 417.1 | 40.6 | 3.63 | 83.7 |
| B-33 | 252.28 | 26.2 | 386.9 | 41.2 | 3.50 | 19.4 |
| B-34 | 264.28 | 21.1 | 411.5 | 40.5 | 4.14 | 14.3 |
| B-35 | 396.39 | 199.8 | 686.3 | 40.6 | 3.27 | 193 0 |
| B-36 | 212.24 | 4.5 | 284.7 | 32.8 | 3.27 | 2.3 |
| H-l | 246.26 | 9.7 | 388.2 | 39.3 | 3.20 | 2.9 |
| H-2 | 336.39 | Solid | 576.8 | 42.2 | 2.65 | — |
| H-3 | 776.92 | 610.0 | — | 37.6 | 4.26 | 603.2 |
| H-4 | 198.22 | 8.0 | — | 36.2 | 4.67 | 1.2 |

A proportion of a non-volatile component in the composition for forming an underlayer film for imprints is preferably 5.0% by mass or less, is more preferably 2.0% by mass or less, is even more preferably 1.0% by mass or less, and is still even more preferably 0.5% by mass or less. The lower limit value thereof is not particularly limited, but it is 0.01% by mass or more from the viewpoint of practicality. As described above, by incorporating a small amount of non-volatile component so that the composition is mainly composed of a solvent, the composition can be applied thinly to a substrate, and it becomes easy to form a nanometer-order thin and uniform film.

Although a proportion of the polyfunctional (meth)acrylate in the non-volatile component in the composition for forming an underlayer film for imprints is not particularly limited, it is preferably 70% by mass or more, is more preferably 80% by mass or more, is even more preferably 90% by mass or more, is still more preferable 95% by mass or more, and is yet more preferable 97% by mass or more. The upper limit thereof is not particularly limited, but it is 100% by mass or less from the viewpoint of practicality. In the present specification, the non-volatile component refers to a component that is liquid at 23° C. and has a boiling point of 250° C. or lower.

Only one type of polyfunctional (meth)acrylate may be contained, or two or more types of thereof may be contained. In a case where two or more types of (meth)acrylates are contained, the total amount thereof is preferably within the above range.

### Compound Having Reactive Group

The composition for forming an underlayer film for imprints may include a compound having a reactive group, in addition to the polyfunctional (meth)acrylate having at least one kind selected from aromatic rings or aromatic heterocyclic rings. Examples of the reactive group include crosslinkable groups, such as an ethylenically unsaturated group (referring to a group containing an ethylenically unsaturated bond) and an epoxy group, among which an ethylenically unsaturated group is preferable. Examples of the ethylenically unsaturated group include a (meth)acryloyl group, an allyl group, and a vinyl group, among which a (meth)acryloyl group is more preferable and an acryloyl group is still more preferable. The (meth)acryloyl group is preferably a (meth)acryloyloxy group. The compound having a reactive group may contain two or more types of reactive groups in one molecule, or may contain two or more reactive groups of the same type in one molecule. The compound having a reactive group is preferably a compound containing one to three reactive groups in one molecule, and more preferably a compound containing two reactive groups in one molecule.

In addition, a molecular weight of the compound having a reactive group is preferably 200 to 1,000 and is more preferably 200 to 900.

In the composition for forming an underlayer film for imprints, a proportion of the compound (excluding the polyfunctional (meth)acrylate having at least one kind selected from aromatic rings or aromatic heterocyclic rings) having a reactive group in the non-volatile component is preferably 50% by mass or less, is more preferably 30% by mass or less, is even more preferably 10% by mass or less, is still more preferably 5% by mass or less, is yet more preferably 3% by mass or less, and is still yet more preferably 1% by mass or less. The lower limit value thereof is not particularly limited, but it is 0.01% by mass or more from the viewpoint of practicality.

Only one type of compound having a reactive group may be contained, or two or more types of compounds having a reactive group may be contained. In a case where two or more types of compounds having a reactive group are contained, the total amount thereof is preferably within the above range.

### Alkylene Glycol Compound

The composition for forming an underlayer film for imprints may include an alkylene glycol compound. The alkylene glycol compound preferably has 3 to 1,000 alkylene glycol structural units, more preferably 4 to 500 alkylene glycol structural units, still more preferably 5 to 100 alkylene glycol structural units, and even still more preferably 5 to 50 alkylene glycol structural units. The weight-average molecular weight (Mw) of the alkylene glycol compound is preferably 150 to 10,000, more preferably 200 to 5,000, still more preferably 300 to 3,000, and even still more preferably 300 to 1,000.

Examples of alkylene glycol compounds include (poly)ethylene glycol, (poly)propylene glycol, mono- or dialkyl ethers or alkyl esters thereof (mono- or dimethyl ether, mono- or dioctyl ether, mono- or dinonyl ether, mono- or didecyl ether, monostearic acid ester, monooleic acid ester, monoadipic acid ester, monosuccinic acid ester), among which (poly)ethylene glycol, (poly)propylene glycol, or derivatives thereof (alkyl ether or alkyl ester) are preferable. In the present specification, in a case where the term “poly” is referred to using parentheses as in “(poly),” this indicates that a compound may be a monomer or a polymer.

The surface tension of the alkylene glycol compound at 23° C. is preferably 38 mN/m or more, and more preferably 40 mN/m or mere. The upper limit of the surface tension is not specifically defined, but it is, for example, 48 mN/m or less. By blending such a compound, the wettability of the curable composition for imprints provided immediately above the underlayer film can be further improved.

A boiling point of the alkylene glycol compound is not particularly limited, but it is preferably 50° C. or higher and is more preferably 70° C. or higher. The upper limit thereof is not particularly defined, but it is, for example, 200° C. or lower. By blending in such a compound, it becomes easy to form a thin underlayer film having favorable volatility.

In a case where the alkylene glycol compound is incorporated, a proportion thereof in the non-volatile component in the composition for forming an underlayer film for imprints is preferably 40% by mass or less, is more preferably 30% by mass or less, is even more preferably 20% by mass or less, and is still even more preferably 10% by mass or less. The lower limit value thereof is not particularly limited, but it is 0.01% by mass or more from the viewpoint of practicality.

Only one type of alkylene glycol compound may be used, or two or more types of alkylene glycol compounds may be used. In a case where two or more types of alkylene glycol compounds are used, the total amount thereof is preferably within the above range.

### Polymerization Initiator

The composition for forming an underlayer film for imprints may or may not include a polymerization initiator. In a case where a polymerization initiator is not included, the polymerization initiator incorporated into the curable composition for imprints can diffuse into the underlayer film and promote polymerization of a reactive compound in the underlayer film. Even in a case where an amount of diffusion is not sufficient, chain of a polymerization reaction initiated by an initiator in the curable composition can promote polymerization of the underlayer film and a reactive compound in the underlayer film. Meanwhile, by incorporating a polymerization initiator in the composition for forming an underlayer film for imprints, polymerization of a reactive compound in the underlayer film can be promoted.

Examples of the polymerization initiator include a thermal polymerization initiator and a photopolymerization initiator. A photopolymerization initiator is preferable from the viewpoint of improving the crosslinking reactivity with the curable composition for imprints. As the photopolymerization initiator, a radical polymerization initiator and a cationic polymerization initiator are preferable, and a radical polymerization initiator is more preferable. In the present invention, a plurality of photopolymerization initiators may be used in combination.

Any of known compounds can be used as the photo-radical polymerization initiator. Examples thereof include a halogenated hydrocarbon derivative (for example, a compound having a triazine skeleton, a compound having an oxadiazole skeleton, or a compound having a trihalomethyl group), an acylphosphine compound such as acylphosphine oxide, hexaarylbiimidazole, an oxime compound such as oxime derivative, an organic peroxide, a thio compound, a ketone compound, an aromatic onium salt, a ketoxime ether, an aminoacetophenone compound, a hydroxyacetophenone, an azo-based compound, an azide compound, a metallocene compound, an organoboron compound, and an iron arene complex. With respect to details thereof, reference can be made to the descriptions in paragraphs 0165 to 0182 of JP2016-027357A, the contents of which are incorporated herein.

The acylphosphine compound may be, for example, 2,4,6-trimethylbenzoyl-diphenyl-phosphine oxide. In addition, IRGACURE-819 and IRGACURE-TPO (trade names: both manufactured by BASF Corporation) which are commercially available products can be used.

In a case of being blended, the content of the polymerization initiator used in the composition for forming an underlayer film for imprints is, for example, 0.01% to 15% by mass, preferably 0.1% to 12% by mass, and more preferably 0.2% to 7% by mass in the non-volatile component.

The polymerization initiator may be used alone or in combination of two or more kinds thereof. In a case of using two or more kinds thereof, it is preferable that a total amount thereof be within the above-mentioned range.

### Other Non-Volatile Components

As the non-volatile component blended in the composition for forming an underlayer film for imprints, one type or two or more types of a polymerization inhibitor, an antioxidant, a leveling agent, a thickener, a surfactant, and the like may be contained in addition to the above-mentioned compounds.

Examples of polymerization inhibitors include an amine-based polymerization inhibitor, a phenol-based polymerization inhibitor, a phosphorus-based polymerization inhibitor, a sulfur-based polymerization inhibitor, a radical-based polymerization inhibitor, a phenothiazine polymerization inhibitor, or combinations thereof, among which a phenol-based polymerization inhibitor, a phosphorus-based polymerization inhibitor, a sulfur-based polymerization inhibitor, a radical-based polymerization inhibitor, or combinations thereof are preferable.

In the present invention, a configuration may be adopted in which the non-volatile component of the composition for forming an underlayer film for imprints does not substantially contain a compound other than the polyfunctional (meth)acrylate having at least one kind selected from aromatic rings or aromatic heterocyclic rings. The phrase “substantially free of” means that the content is 0.1% by mass or less of the non-volatile component in the composition for forming an underlayer film for imprints.

In the present invention, the composition for forming an underlayer film for imprints preferably does not substantially include a compound having at least two thiol groups. The phrase “substantially free of” means that the content is 0.1% by mass or less of the non-volatile component in the composition for forming an underlayer film for imprints. By adopting such a configuration, temporal stability of a solution of the composition for forming an underlayer film for imprints tends to be exhibited more effectively.

### Solvent

The composition for forming an underlayer film for imprints contains a compound (solvent) that is liquid at 23° C. and has a boiling point of 300° C. or lower in a proportion of preferably 99.0% by mass or more and more preferably 99.5% by mass or more. The proportion of the solvent may be 99.6% by mass or more. The upper limit thereof is not particularly limited, but it is 99.99% by mass or less from the viewpoint of practicality. In the present invention, the liquid means that the viscosity at 23° C. is 100,000 mPa·s or less.

The composition for forming an underlayer film for imprints may contain only one type of solvent, or may contain two or more types of solvents. In a case where two or more types of solvents are contained, the total amount thereof is preferably within the above range.

Among the above solvents, the boiling point of the component having the highest content is preferably 180° C. or lower, more preferably 160° C. or lower, and still more preferably 130° C. or lower. By adopting a solvent having a boiling point of the above-mentioned range or less, the solvent can be easily removed from the underlayer film. In the present invention, among the solvents contained in the composition for forming an underlayer film for imprints, preferably 90% by mass or more, more preferably 93% by mass or more, still more preferably 95% by mass or more, and even still more preferably 99% by mass or more thereof is a solvent satisfying the condition of above boiling point.

The solvent is preferably an organic solvent. The solvent is preferably a solvent having any one or more of the group consisting of an ester group, a carbonyl group, a hydroxyl group, and an ether group.

Specific examples of the solvent include a propylene glycol monoalkyl ether carboxylate, a propylene glycol monoalkyl ether, a lactate, an acetate, an formate an alkoxypropionate, a chain ketone, a cyclic ketone, a lactone, and an alkylene carbonate.

The propylene glycol monoalkyl ether carboxylate is preferably at least one selected from the group consisting of propylene glycol monomethyl ether acetate, propylene glycol monomethyl ether propionate, and propylene glycol monoethyl ether acetate, and particularly preferably propylene glycol monomethyl ether acetate.

The propylene glycol monoalkyl ether is preferably propylene glycol monomethyl ether or propylene glycol monoethyl ether.

The lactate is preferably ethyl lactate, butyl lactate, or propyl lactate.

The acetate or the formate is preferably methyl acetate, ethyl acetate, butyl acetate, isobutyl acetate, propyl acetate, isoamyl acetate, methyl formate, ethyl formate, butyl formate, propyl formate, or 3-methoxybutyl acetate.

The alkoxypropionate is preferably methyl 3-methoxypropionate (MMP) or ethyl 3-ethoxypropionate (EEP).

The chain ketone is preferably 1-octanone, 2-octanone, 1-nonanone, 2-nonanone, acetone, 4-heptanone, 1-hexanone, 2-hexanone, diisobutylketone, phenylacetone, methyl ethyl ketone, methyl isobutyl ketone, acetylacetone, acetonyl acetone, ionone, diacetonyl alcohol, acetyl carbinol, acetophenone, methyl naphthyl ketone, or methyl amyl ketone.

The cyclic ketone is preferably methylcyclohexanone, isophorone, or cyclohexanone.

The lactone is preferably γ-butyrolactone.

The alkylene carbonate is preferably propylene carbonate.

In addition to the above-mentioned components, it is preferable to use an ester-based solvent having 7 or more carbon atoms (preferably 7 to 14, more preferably 7 to 12, and still more preferably 7 to 10) and 2 or less hetero atoms.

Preferred examples of the ester-based solvent having 7 or more carbon atoms and 2 or less hetero atoms include amyl acetate, 2-methylbutyl acetate, 1-methylbutyl acetate, hexyl acetate, pentyl propionate, hexyl propionate, butyl propionate, isobutyl isobutyrate, heptyl propionate, and butyl butanoate.

In addition, it is also preferable to use one having a flash point (hereinafter, also referred to as fp) of 37° C. or higher. Such a component is preferably propylene glycol monomethyl ether (fp: 47° C.), ethyl lactate (fp: 53° C.), ethyl 3-ethoxypropionate (fp: 49° C.), methyl amyl ketone (fp: 42° C.), cyclohexanone (fp: 40° C.), pentyl acetate (fp: 45° C.), methyl 2-hydroxyisobutyrate (fp: 45° C.), γ-butyrolactone (fp: 101° C.) or propylene carbonate (fp: 132° C.). Among these, propylene glycol monomethyl ether, ethyl lactate, pentyl acetate, or cyclohexanone is more preferable, and propylene glycol monomethyl ether or ethyl lactate is particularly preferable. Here, the “flash point” refers to a value described in a reagent catalog of Tokyo Chemical Industry Co., Ltd. or Sigma-Aldrich Co. LLC.

A more preferred solvent is at least one selected from the group consisting of water, propylene glycol monomethyl ether acetate (PGMEA), ethoxyethyl propionate, cyclohexanone, 2-heptanone, γ-butyrolactone, butyl acetate, propylene glycol monomethyl ether (PGME), ethyl lactate, and 4-methyl-2-pentanol, and a still more preferred solvent is at least one selected from the group consisting of PGMEA and PGME.

A conventionally known storage container can be used as a storage container for the composition for forming an underlayer film for imprints. In addition, as the storage container, it is also preferable to use a multi-layer bottle in which the inner wall of the container is composed of six types and six layers of resin, or a bottle having a seven-layer structure of six types of resins, for the purpose of suppressing the incorporation of impurities into raw materials and compositions. Examples of such a container include containers described in JP2015-123351A.

### Curable Composition for Imprints

Next, the curable composition for imprints which can be used in the embodiment of the present invention will be described.

The curable composition for imprints is not particularly defined, and a known curable composition for imprints can be used and preferably contains at least a polymerizable compound.

### Viscosity

It is preferable to design the curable composition for imprints to have a low viscosity and a high surface tension in order to make use of capillary force and enable high-speed filling into a mold pattern. Specifically, the viscosity of the curable composition for imprints at 23° C. is preferably 20.0 mPa·s or less, more preferably 15.0 mPa·s or less, still more preferably 11.0 mPa·s or less, and even still more preferably 9.0 mPa·s or less. The lower limit value of the viscosity is not particularly limited, but may be, for example, 5.0 mPa·s or more. The viscosity is measured according to the method described in the Examples, which will be described later. In the present invention, a viscosity (η2) of the curable composition for imprints and a viscosity (η1) of the polyfunctional (meth)acrylate included in the composition for forming an underlayer film for imprints are preferably adjusted in an absolute value (Δη) of a difference therebetween, and a range thereof is as described above.

In addition, a case in which a difference of a surface tension of the curable composition for imprints and a surface tension of the non-volatile component included in the composition for forming an underlayer film for imprints is smaller is preferable, and it is preferably 30 mN/m or less and is more preferably 5 mN/m or less.

In addition, 80% or more of a polymerizable group contained in a polymerizable compound included in the curable composition for imprints, and a polymerizable group contained in the polyfunctional (meth)acrylate included in the composition for forming an underlayer film for imprints are preferably the same polymerizable group. A case where those polymerizable groups are the same polymerizable groups is preferable because then a difference in reactivity of the underlayer film and the curable composition for imprints becomes small.

### Surface Tension

A surface tension (γ Resist) of the curable composition for imprints at 23° C. is preferably 30 mN/m or more and is more preferably 31 mN/m or more. Use of the curable composition for imprints having a high surface tension leads to an increase in capillary force and enables high speed filling of the curable composition for imprints into a mold pattern. The upper limit value of the surface tension is not particularly limited, but it is preferably 40 mN/m or less and more preferably 38 mN/m or less from the viewpoint of importing the relationship with the underlayer film and ink jet suitability, and may be 36 mN/m or less.

The surface tension of the curable composition for imprints at 23° C. is measured according to the method described in the Examples, which will be described later.

### Ohnishi Parameter

An Ohnishi parameter of the curable composition for imprints is preferably 5.0 or less, is more preferably 4.5 or less, is even more preferably 4.0 or less, and is still more preferably 3.5 or less. The lower limit value of the Ohnishi parameter of the non-volatile component is not particularly defined, but may be, for example, 2.5 or more, further 3.0 or more. The Ohnishi parameter is calculated according to the method described in the Examples, which will be described later.

### Content Percentage and the Like

In the present invention, the content of the solvent in the curable composition for imprints is preferably 5% by mass or less, more preferably 3% by mass or less, and still more preferably 1% by mass or less of the curable composition for imprints.

In addition, the curable composition for imprints can also be made into an aspect which is substantially free of a polymer (a polymer having a weight-average molecular weight of preferably more than 10,000, more preferably more than 2,000, and still more preferably 1,000 or more). The phrase “substantially free of a polymer” means, for example, that the polymer content is 0.01% by mass or less of the curable composition for imprints. It is preferable that the polymer content is 0.005% by mass or less, and it is more preferable that the curable composition for imprints contains no polymer at all.

### Polymerizable Compound

The curable composition for imprints preferably contains a polymerizable compound, and the polymerizable compound contained in the curable composition for imprints may be a monofunctional polymerizable compound, may be a polyfunctional polymerizable compound, or may be a mixture of both. In addition, at least a part of the polymerizable compound contained in the curable composition for imprints is preferably liquid at 23° C., and more preferably 15% by mass or more of the polymerizable compound contained in the curable composition for imprints is liquid at 23° C.

The polymerizable compound preferably has a ring structure, and more preferably has an aromatic ring structure or an aromatic heterocyclic ring structure.

### Monofunctional Polymerizable Compound

The molecular weight of the monofunctional polymerizable compound used in the curable composition for imprints is preferably 50 or more, more preferably 100 or more, and still more preferably 150 or more. In addition, the molecular weight is preferably 1,000 or less, more preferably 800 or less, still more preferably 300 or less, and even still more preferably 270 or less. In a case where the molecular weight is the above-mentioned lower limit value or more, a tendency in which volatility can be inhibited is obtained. In a case where the molecular weight is the above-mentioned upper limit value or less, a tendency in which a viscosity can be reduced is obtained.

The boiling point of the monofunctional polymerizable compound used in the curable composition for imprints is preferably 85° C. or higher, more preferably 110° C. or higher, and still more preferably 130° C. or higher. In a case where the boiling point is the above-mentioned lower limit value or more, volatility can be inhibited. The upper limit value of the boiling point is not particularly defined, but for example, the boiling point can be set to 350° C. or lower.

The type of the polymerizable group which is contained in the monofunctional polymerizable compound used in the curable composition for imprints is not specifically defined, and examples thereof include an ethylenically unsaturated group and an epoxy group, among which an ethylenically unsaturated group is preferable. Examples of the ethylenically unsaturated group include a (meth)acryloyl group and a vinyl group, among which a (meth)acryloyl group is more preferable and an acryloyl group is still more preferable. The (meth)acryloyl group is preferably a (meth)acryloyloxy group.

The type of atoms constituting the monofunctional polymerizable compound used in the curable composition for imprints is not particularly defined, but the monofunctional polymerizable compound is preferably constituted of only atoms selected from a carbon atom, an oxygen atom, a hydrogen atom, and a halogen atom, and is more preferably constituted of only atoms selected from a carbon atom, an oxygen atom, and a hydrogen atom.

A preferred first embodiment of the monofunctional polymerizable compound used in the curable composition for imprints is a compound having a linear or branched hydrocarbon chain having 4 or more carbon atoms.

The hydrocarbon chain in the present invention represents an alkyl chain, an alkenyl chain, or an alkynyl chain, preferably an alkyl chain or alkenyl chain, and more preferably an alkyl chain.

In the present invention, the alkyl chain represents an alkyl group and an alkylene group. Similarly, the alkenyl chain represents an alkenyl group and an alkenylene group, and the alkynyl chain represents an alkynyl group and an alkynylene group. Among these, a linear or branched alkyl group or alkenyl group is more preferable, a linear or branched alkyl group is still more preferable, and a linear alkyl group is even still more preferable.

The linear or branched hydrocarbon chain (preferably an alkyl group) has 4 or more carbon atoms, preferably 6 or more carbon atoms, more preferably 8 or more carbon atoms, still more preferably 10 or more carbon atoms, and even still more preferably 12 or more carbon atoms. The upper limit value of the number of carbon atoms is not particularly defined, but can be, for example, 25 or less.

The linear or branched hydrocarbon chain may contain an ether group (—O—), but it is preferable not to contain an ether group from the viewpoint of improving releasability.

By using a monofunctional polymerizable compound having such a hydrocarbon chain, a relatively small addition amount thereof results in reduced modulus of elasticity of the cured product (pattern), thereby improving the releasability. In addition, in a case where a monofunctional polymerizable compound having a linear or branched alkyl group is used, the interfacial energy between the mold and the cured product (pattern) can be reduced, and thus the releasability can be further improved.

Preferred hydrocarbon groups which are contained in the monofunctional polymerizable compound used in the curable composition for imprints include the following (1) to (3).

(1) a linear alkyl group having 8 or more carbon atoms

(2) a branched alkyl group having 10 or more carbon atoms

(3) an alicyclic ring, aromatic ring, or aromatic heterocyclic ring substituted with a linear or branched alkyl group having 5 or more carbon atoms

(1) a linear alkyl group having 8 or more carbon atoms

The linear alkyl group having 8 or more carbon atoms is more preferably one having 10 or more carbon atoms, still more preferably 11 or more carbon atoms, and even still more preferably 12 or more carbon atoms. In addition, the number of carbon atoms in the linear alkyl group having 8 or more carbon atoms is preferably 20 or less, more preferably 18 or less, still more preferably 16 or less, and even still more preferably 14 or less.

(2) a branched alkyl group having 10 or more carbon atoms

The branched alkyl group having 10 or more carbon atoms is preferably one having 10 to 20 carbon atoms, more preferably 10 to 16 carbon atoms, still more preferably 10 to 14 carbon atoms, and particularly even still more preferably 10 to 12 carbon atoms.

(3) an alicyclic ring, aromatic ring, or aromatic heterocyclic ring substituted with a linear or branched alkyl group having 1 or more carbon atoms

The linear or branched alkyl group having one or more carbon atoms is more preferably a linear alkyl group. The number of carbon atoms in the alkyl group is preferably 14 or less, more preferably 12 or less, and still more preferably 10 or less.

The ring of the alicyclic, aromatic, or aromatic heterocyclic ring may be a monocyclic ring or a fused ring, but is preferably a monocyclic ring. In a case of a fused ring, the number of rings is preferably 2 or 3. The ring is preferably a 3- to 8-membered ring, more preferably a 5- or 6-membered ring, and still more preferably a 6-membered ring. Specific examples of the ring include a cyclohexane ring, a norbornane ring, an isobornane ring, a bornane ring, a tricyclodecane ring, a tetracyclododecane ring, an adamantane ring, a benzene ring, a naphthalene ring, an anthracene ring, and a fluorene ring. Among these, a cyclohexane ring, a bornane ring, a tricyclodecane ring, an adamantane ring, and a benzene ring are more preferable, and a benzene ring is still more preferable.

The monofunctional polymerizable compound used in the curable composition for imprints is preferably a compound in which a linear or branched hydrocarbon chain having 4 or more carbon atoms and a polymerizable group are bonded to each other directly or through a linking group; and more preferably a compound in which any one of the above groups (1) to (3) and a polymerizable group are directly bonded to each other. Examples of the linking group include —O—, —C(═O)—, —CH₂—, and a combination thereof. The monofunctional polymerizable compound used in the present invention is particularly preferably a linear alkyl(meth)acrylate in which a linear alkyl group having 8 or more carbon atoms (1) and a (meth)acryloyloxy group are directly bonded to each other.

Examples of the monofunctional polymerizable compound of the first embodiment include the following first group and second group. However, it goes without saying that the present invention is not limited to these groups. In addition, the first group is more preferable than the second group.

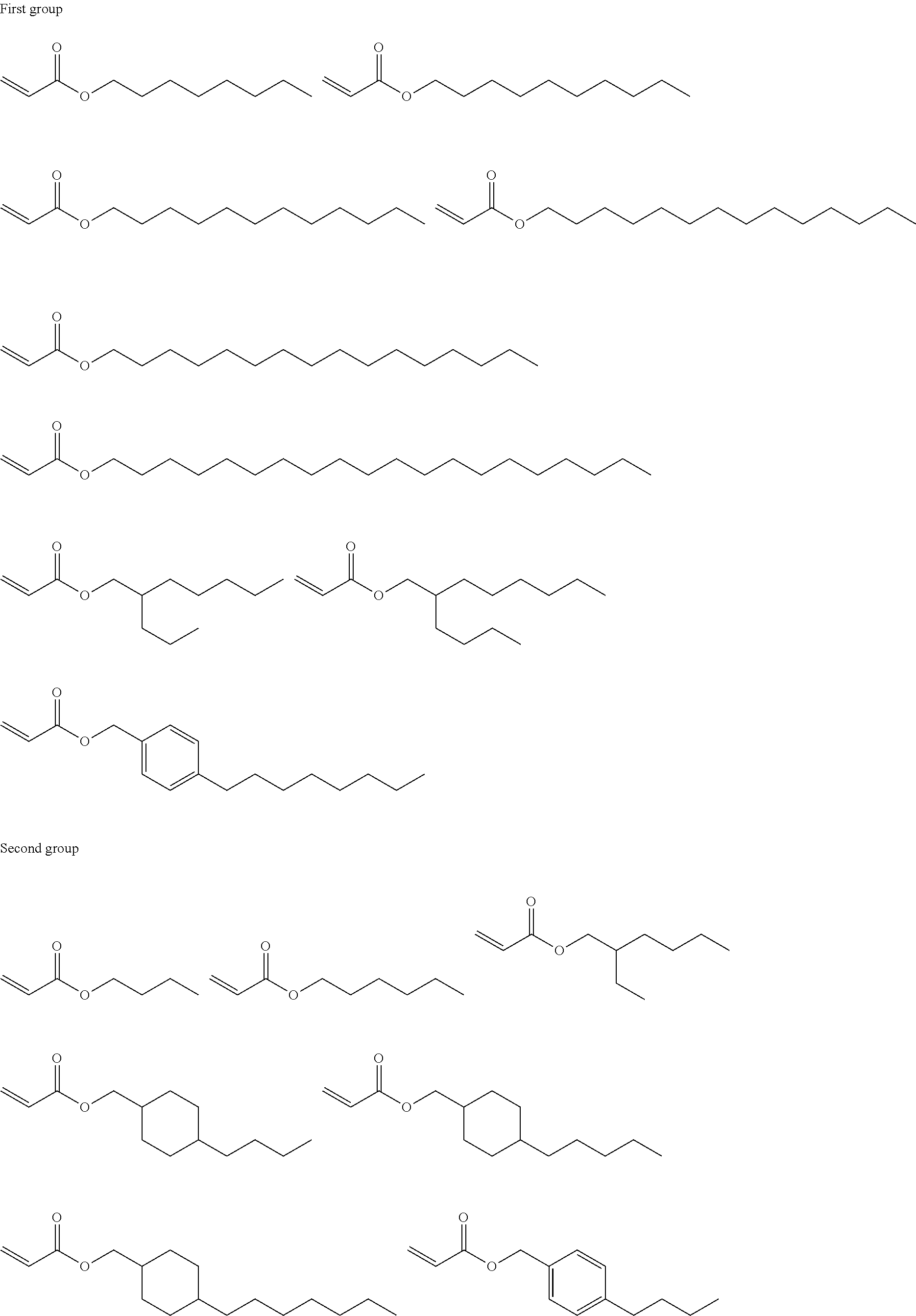

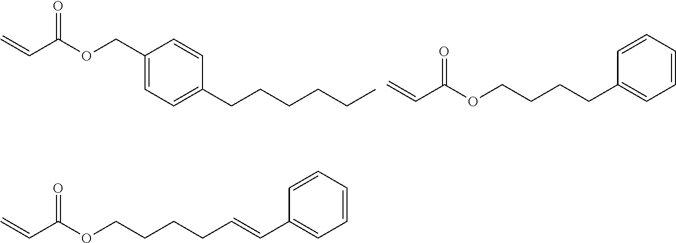

A preferred second embodiment of the monofunctional polymerizable compound used in the curable composition for imprints is a compound having a cyclic structure. The cyclic structure is preferably a 3- to 8-membered monocyclic ring or fused ring. The number of rings constituting the fused ring is preferably 2 or 3. The cyclic structure is more preferably a 5-membered ring or a 6-membered ring, and still more preferably a 6-membered ring. In addition, a monocyclic ring is more preferable.

The number of cyclic structures in one molecule of the polymerizable compound may be one or two or more, but is preferably one or two and more preferably one. In a case of a fused ring, the fused ring is considered as one cyclic structure.

Examples of the monofunctional polymerizable compound according to the second embodiment include the following compounds. However, it goes without saying that the present invention is not limited to these groups.

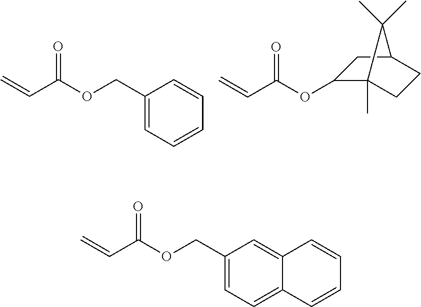

In the present invention, monofunctional polymerizable compounds other than the above-mentioned monofunctional polymerizable compounds may be used as long as it does not depart from the spirit of the present invention, and examples thereof include monofunctional polymerizable compounds among the polymerizable compounds described in JP2014-170949A, the contents of which are incorporated herein.

A content of the monofunctional polymerizable compound used in the curable composition for imprints with respect to the total polymerizable compound is preferably 6% by mass or more, is more preferably 8% by mass or more, is even more preferably 10% by mass or more, and is still more preferably 12% by mass or more. The content of the monofunctional polymerizable compound is more preferably 60% by mass or less, and may be 55% by mass or less.

In the present invention, only one type of monofunctional polymerizable compound may be contained, or two or more types of monofunctional polymerizable compounds may be contained. In a case where two or more types of solvents are contained, the total amount thereof is preferably within the above range.

### Polyfunctional Polymerizable Compound

Meanwhile, a polyfunctional polymerizable compound used in the curable composition for imprints is not particularly defined, but it preferably contains at least one alicyclic ring, aromatic ring, or aromatic heterocyclic ring, and more preferably contains at least one aromatic ring or aromatic heterocyclic ring. In the following description, a compound containing at least one of an alicyclic ring, an aromatic ring, or an aromatic heterocyclic ring may be referred to as a ring-containing polyfunctional polymerizable compound. By the use of a ring-containing polyfunctional polymerizable compound, in combination with the use of the polyfunctional (meth)acrylate having at least one kind selected from aromatic rings or aromatic heterocyclic rings in the composition for forming an underlayer film for imprints, interfacial tension between the curable composition for imprints and the underlayer film for imprints is reduced, and thereby compatibility becomes excellent, and wettability with respect to the underlayer film is improved. Furthermore, etching resistance of a pattern forming layer is also improved.

The molecular weight of the ring-containing polyfunctional polymerizable compound used in the curable composition for imprints is preferably 1,000 or less, more preferably 800 or less, still more preferably 500 or less, and even still more preferably 350 or less. By setting the upper limit value of the molecular weight to 1,000 or less, the viscosity tends to be reduced. The lower limit value of the molecular weight is not particularly defined, but can be, for example, 200 or more.

The number of polymerizable groups contained in the ring-containing polyfunctional polymerizable compound used in the curable composition for imprints is 2 or more, preferably 2 to 7, more preferably 2 to 4, still more preferably 2 or 3, and even still more preferably 2.

The type of polymerizable group contained in the ring-containing polyfunctional polymerizable compound used in the curable composition for imprints is not particularly defined, and examples thereof include an ethylenically unsaturated group and epoxy group, among which an ethylenically unsaturated group is preferable. Examples of the ethylenically unsaturated group include a (meth)acryloyl group and a vinyl group, among which a (meth)acryloyl group is more preferable and an acryloyl group is still more preferable. The (meth)acryloyl group is preferably a (meth)acryloyloxy group. Two or more types of polymerizable groups may be contained in one molecule, or two or more polymerizable groups of the same type may be contained in one molecule.

The type of atoms constituting the ring-containing polyfunctional polymerizable compound used in the curable composition for imprints is not particularly defined, but the ring-containing polyfunctional polymerizable compound is preferably constituted of only atoms selected from a carbon atom, an oxygen atom, a hydrogen atom, and a halogen atom, and is more preferably constituted of only atoms selected from a carbon atom, an oxygen atom, and a hydrogen atom.

The ring contained in the ring-containing polyfunctional polymerizable compound used in the curable composition for imprints may be a monocyclic ring or a fused ring, but is preferably a monocyclic ring. In a case of a fused ring, the number of rings is preferably 2 or 3. The ring is preferably a 3- to 8-membered ring, more preferably a 5- or 6-membered ring, and still more preferably a 6-membered ring. In addition, the ring may be an alicyclic ring, an aromatic ring or an aromatic heterocyclic ring, but it is preferably an aromatic ring or an aromatic heterocyclic ring, and is more preferably an aromatic ring. Specific examples of the ring include a cyclohexane ring, a norbornane ring, an isobornane ring, a tricyclodecane ring, a tetracyclododecane ring, an adamantane ring, a benzene ring, a naphthalene ring, an anthracene ring, and a fluorene ring. Among these, a cyclohexane ring, a tricyclodecane ring, an adamantane ring, and a benzene ring are more preferable, and a benzene ring is still more preferable. Alternatively, examples of the ring Cy and ring hCy exemplified in regards to the polyfunctional (meth)acrylate of the composition for forming an underlayer film for imprints is exemplified.

The number of rings in the ring-containing polyfunctional polymerizable compound used in the curable composition for imprints may be one or two or more, but is preferably one or two and more preferably one. In a case of a fused ring, the fused ring is considered as one ring.

The structure of the ring-containing polyfunctional polymerizable compound used in the curable composition for imprints is preferably represented by (polymerizable group)-(single bond or divalent linking group)-(divalent group having a ring)-(single bond or a divalent linking group)-(polymerizable group). Here, the linking group is more preferably an alkylene group, and still more preferably an alkylene group having 1 to 3 carbon atoms.

The ring-containing polyfunctional polymerizable compound used in the curable composition for imprints is preferably represented by Formula (I-1).

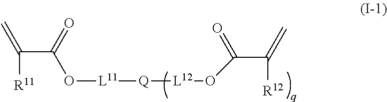

Q represents a divalent group having at least one kind selected from alicyclic rings, aromatic rings, or aromatic heterocyclic rings. R¹¹ and R¹² each independently represent a hydrogen atom or a methyl group. L¹¹ and L¹² each independently represent a single bond or the linking group L. Q and L¹¹ or L¹² may be bonded to each other via or without a linking group L to form a ring. Q, L¹¹, and L¹² may have the substituent T. A plurality of substituents T may be bonded to form a ring, or may be bonded to Q or bonded to L¹¹ or L¹² to form a ring. In a case where there are a plurality of substituents T, they may be the same as or different from each other. The preferred range of the alicyclic ring, aromatic rings, or aromatic heterocyclic rings in Q is the same as described above. Alternatively, examples of the ring Cy and the ring hCy are exemplified. q is an integer of 1 to 4, is preferably an integer of 1 to 3, is more preferably an integer of 1 or 2, and is still more preferably an integer of 1.

In the present invention, the polyfunctional polymerizable compound included in the curable composition for imprints is preferably selected from polyfunctional (meth)acrylates included in the composition for forming an underlayer film for imprints. Although it is not essential that both are the same, an aspect is exemplified in which some or all of polyfunctional polymerizable compounds included in the curable composition for imprints and polyfunctional (meth)acrylates included in the composition for forming an underlayer film for imprints are common. It is preferable that they are the same as each other. By using the same kind of or the same polyfunctional (meth)acrylates in the curable composition for imprints and the composition for forming an underlayer film for imprints, the layer of the curable composition for imprints and the underlayer film become easily compatible, and thereby uniformity in wettability and etching process resistance tends to be improved.

Examples of the polyfunctional polymerizable compound used in the curable composition for imprints include the following first group and second group. However, it goes without saying that the present invention is not limited to these groups. The first group is more preferable. Alternatively, examples of the polyfunctional (meth)acrylate exemplified for the composition for forming an underlayer film for imprints are exemplified.

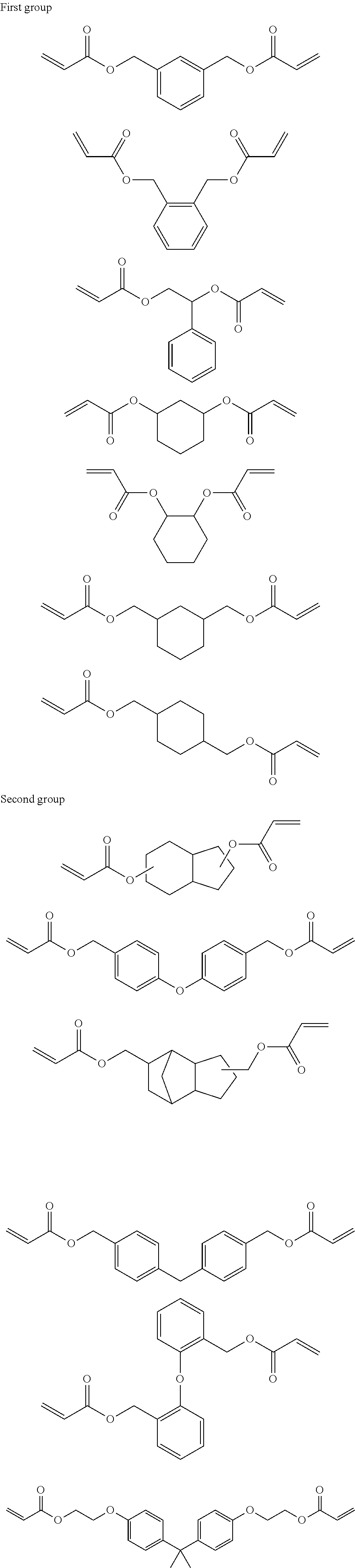

The curable composition for imprints may contain polyfunctional polymerizable compounds other than the ring-containing polyfunctional polymerizable compound.

Examples of other polyfunctional polymerizable compounds used in the curable composition for imprints include polyfunctional polymerizable compounds having no ring among the polymerizable compounds described in JP2014-170949A, the contents of which are incorporated herein. More specifically, for example, the following compounds are exemplified.

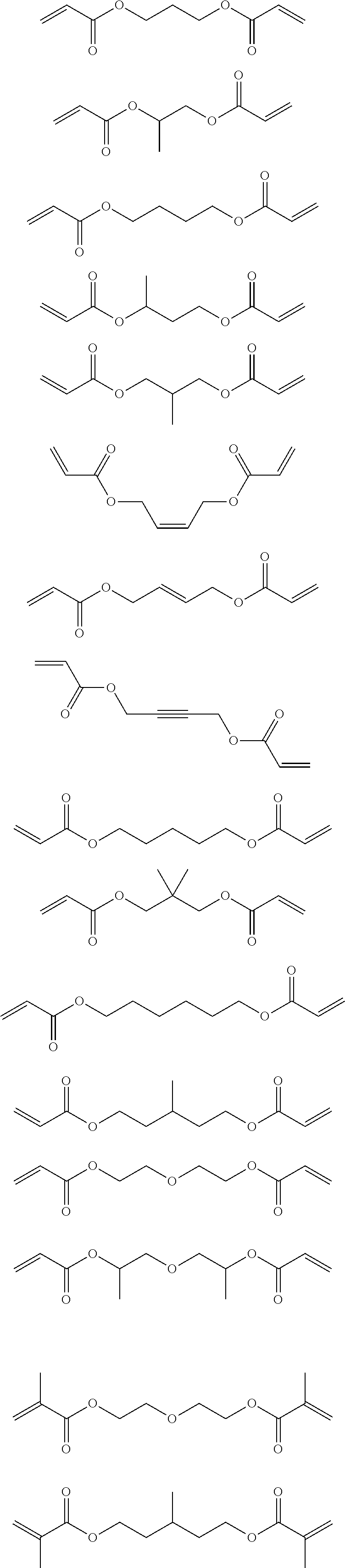

The content of the polyfunctional polymerizable compound is preferably 30% by mass or more, more preferably 45% by mass or more, still more preferably 50% by mass or more, and even still more preferably 55% by mass or more, and may be 60% by mass or more, and may be 70% by mass or more, with respect to the total polymerizable compound in the curable composition for imprints. In addition, the upper limit value of the content of the polyfunctional polymerizable compound is preferably less than 95% by mass and more preferably 90% by mass or less, and it can also be 85% by mass or less. In particular, in a case where a content of the ring-containing polyfunctional polymerizable compound is the above-mentioned lower limit value or more, and polyfunctional (meth)acrylate having at least one kind selected from aromatic rings or aromatic heterocyclic rings in the composition for forming an underlayer film for imprints is adopted, it is possible to obtain a composition having excellent compatibility between the curable composition for imprints and the underlayer film and excellent etching workability.

The curable composition for imprints may contain only one type of polyfunctional polymerizable compound or may contain two or more types of polyfunctional polymerizable compounds. In a case where two or more types of solvents are contained, the total amount thereof is preferably within the above range.

In the curable composition for imprints used in the embodiment of the present invention, preferably 85% by mass or more, more preferably 90% by mass or more, and still more preferably 93% by mass or more of the composition is a polymerizable compound.

### Other Components

The curable composition for imprints may contain additives other than the polymerizable compound. Other additives may include a surfactant, a sensitizer, a mold release agent, an antioxidant, a polymerization inhibitor, and the like.

Examples of polymerization inhibitors include an amine-based polymerization inhibitor, a phenol-based polymerization inhibitor, a phosphorus-based polymerization inhibitor, a sulfur-based polymerization inhibitor, a radical-based polymerization inhibitor, a phenothiazine polymerization inhibitor, or combinations thereof, among which a phenol-based polymerization inhibitor, a phosphorus-based polymerization inhibitor, a sulfur-based polymerization inhibitor, a radical-based polymerization inhibitor, or combinations thereof are preferable.

Specific examples of the curable composition for imprints that can be used in the embodiment of the present invention include compositions described in the Examples which will be described later, and compositions described in JP2013-036027A, JP2014-090133A, and JP2013-189537A, the contents of which are incorporated herein. In addition, the preparation of the curable composition for imprints and the formation method of the film (pattern forming layer) can be referred to the description in the above-mentioned patent publications, the contents of which are incorporated herein.

A conventionally known storage container can be used as a storage container for the curable composition for imprints used in the embodiment of the present invention. In addition, as the storage container, it is also preferable to use a multi-layer bottle in which the inner wall of the container is composed of six types and six layers of resin, or a bottle having a seven-layer structure of six types of resins, for the purpose of suppressing the incorporation of impurities into raw materials and compositions. Examples of such a container include containers described in JP2015-123351A.

### Kit

In the present invention, the kit that includes the composition for forming an underlayer film for imprints which has the polyfunctional (meth)acrylate containing at least one aromatic ring or aromatic heterocyclic ring, and that includes the curable composition for imprints is preferable. The form of the kit is not particularly limited, but both may be the same package or different packages. It may be specified in a specification or the like that both are used in combination. It is preferable that the curable composition for imprints include a polyfunctional (meth)acrylate, and the polyfunctional (meth)acrylate in the curable composition for imprints have at least one aromatic ring or aromatic heterocyclic ring. In the kit of the embodiment of the present invention, a viscosity (η1) of the polyfunctional (meth)acrylate used in the composition for forming an underlayer film for imprints and a viscosity (η2) of the curable composition for imprints are preferably within the range shown above, and an absolute value (Δη) of a difference therebetween is preferably within the above-mentioned range.

### Method for Producing Cured Product Pattern

The method for producing a cured product pattern according to the embodiment of the present invention is a method for producing a cured product pattern using the kit according to the embodiment of the present invention, which includes an underlayer film forming step of applying a composition for forming an underlayer film for imprints on a substrate to form an underlayer film; an applying step of applying a curable composition for imprints on a surface of the underlayer film; a mold contact step of bringing the curable composition for imprints into contact with a mold having a pattern for transferring a pattern shape; a light irradiation step of irradiating the curable composition for imprints with light to form a cured product; and a mold release step of separating the cured product from the mold.

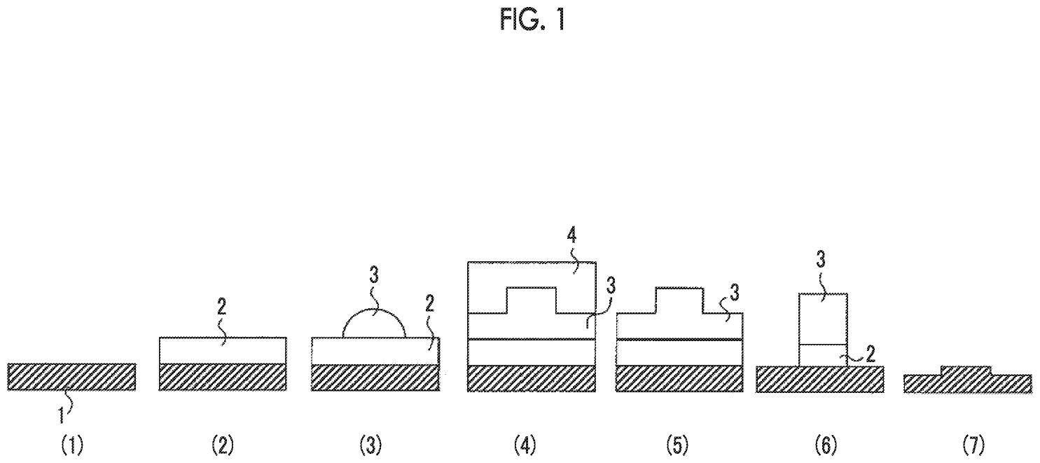

Hereinafter, the method for forming a cured product pattern (the method for producing a cured product pattern) will be described with reference to FIG. 1. Needless to say, the configuration of the present invention is not limited to that shown in FIG. 1.

### Underlayer Film Forming Step

In the underlayer film forming step, an underlayer film 2 is formed on a substrate 1 as shown in FIG. 1(2). The underlayer film is preferably formed by applying the composition for forming an underlayer film for imprints in a layer form on the substrate. The underlayer film may be formed directly on the surface of the substrate 1, or an adhesion film may be provided on the surface of the substrate 1. In a case where the adhesion film is provided, it is preferable to provide the underlayer film on the surface of the adhesion film. For example, a film formed from the composition for forming an underlayer film for imprints described in JP2014-024322A can be used as the adhesion film.

The application method of the composition for forming an underlayer film for imprints on a substrate is not particularly defined, and generally well-known application methods can be employed. Specific examples of the application method include a dip coating method, an air knife coating method, a curtain coating method, a wire bar coating method, a gravure coating method, an extrusion coating method, a spin coating method, a slit scanning method, and an ink jet method, among which a spin coating method is preferable.

In addition, after the composition for forming an underlayer film for imprints is applied in a layer form on the substrate, the solvent is preferably volatilized (dried) by heat to form an underlayer film which is a thin film. In the present invention, as described above, it is preferable to heat (bake) the composition for forming an underlayer film for imprints applied in a layer form at 30° C. to 120° C. (preferably 40° C. or higher and 100° C. or lower). The heating time can be 30 seconds to 5 minutes.

The thickness of the underlayer film 2 is preferably 2 nm or more, more preferably 3 nm or more, and still more preferably 4 nm or more, and may be 5 nm or more or may be 7 nm or more. In addition, the thickness of the underlayer film is preferably 40 nm or less, more preferably 30 nm or less, and still more preferably 20 nm or less. In a case where the film thickness is the above-mentioned lower limit value or more, spreadability (wettability) of the curable composition for imprints on the underlayer film is improved, and therefore a uniform residual film can be formed after imprinting. By setting the film thickness below the upper limit value described above, the residual film after imprinting becomes thin, film thickness unevenness hardly occurs, and therefore the residual film uniformity tends to be improved.

The material of the substrate is not particularly defined, and reference can be made to the description in paragraph 0103 of JP2010-109092A (the publication number of the corresponding US application it US 2011/0183127), the contents of which are incorporated herein. In the present invention, there are, for example, a silicon substrate, a sapphire substrate, a silicon carbide substrate, a gallium nitride substrate, an aluminum substrate, an amorphous aluminum oxide substrate, a polycrystalline aluminum oxide substrate, and a substrate made of GaAsP, GaP, AlGaAs, InGaN, GaN, AlGaN, ZnSe, AlGa, InP, or ZnO. Specific examples of materials for a glass substrate include aluminosilicate glass, aluminoborosilicate glass, and barium borosilicate glass. In the present invention, a silicon substrate is preferable.

### Applying Step

In the applying step, for example, as shown in FIG. 1(3), a curable composition 3 for imprints is applied on the surface of the underlayer film 2.

The method of applying the curable composition for imprints is not particularly defined, and reference can be made to the description in paragraph 0102 of JP2010-109092A (the publication number of the corresponding US application is US 2011/0183127), the contents of which are incorporated herein. The curable composition for imprints is preferably applied on the surface of the underlayer film by an ink jet method. In addition, the curable composition for imprints may be applied by multiple applications. In the method of disposing liquid droplets on the surface of the underlayer film by an inkjet method or the like, the amount of the liquid droplets is preferably about 1 to 20 pL, and it is preferable to dispose the liquid droplets on the surface of the underlayer film with an interval between the liquid droplets. The interval between the liquid droplets is preferably 10 to 1,000 μm. In a case of the ink jet method, the interval between the liquid droplets is set to the arrangement interval between the ink jet nozzles.

Furthermore, the volume ratio between the underlayer film 2 and the film-like curable composition 3 for imprints applied on the substrate is preferably 1:1 to 500, more preferably 1:10 to 300, and still more preferably 1:50 to 200.

That is, as a laminate formed from the kit according to the embodiment of the present invention, the present invention discloses a laminate having an underlayer film which is formed from the above-mentioned composition for forming an underlayer film for imprints and a pattern forming layer which is formed from the above-mentioned curable composition for imprints and is positioned on the surface of the underlayer film.

In addition, the method for producing a laminate according to the embodiment of the present invention is a method for producing a laminate using the kit according to the embodiment of the present invention, which includes applying the curable composition for imprints on the surface of the underlayer film formed from the composition for forming an underlayer film for imprints. Furthermore, the method for producing a laminate according to the embodiment of the present invention preferably includes a step of applying the composition for forming an underlayer film for imprints on a substrate in a layer form, and a step of heating (baking) the composition for forming an underlayer film for imprints applied in a layer form at 30° C. to 90° C. (preferably 40° C. or higher and 80° C. or lower). The heating time can be 30 seconds to 5 minutes.

### Mold Contact Step

In the mold contact step, for example, as shown in FIG. 1(4), the curable composition 3 for imprints and a mold 4 having a pattern for transferring a pattern shape are brought into contact with each other. Through such a step, a desired cured product pattern (imprint pattern) is obtained.

Specifically, the mold 4 is pressed against the surface of the film-like curable composition 3 for imprints in order to transfer a desired pattern to a film-like curable composition for imprints.

The mold may be a light-transmissive mold or a non-light-transmissive mold. In a case where a light-transmissive mold is used, it is preferable to irradiate the curable composition 3 with light from the mold side. On the other hand, in a case where a non-light-transmissive mold is used, it is preferable to use a light-transmissive substrate as the substrate and irradiate with light from the substrate side. In the present invention, it is more preferable to use a light-transmissive mold and irradiate with light from the mold side.

The mold that can be used in the present invention is a mold having a pattern to be transferred. Although the pattern on the mold may be formed according to the desired processing accuracy, for example, by photolithography, electron beam lithography, or the like, the method for producing a mold pattern is not particularly limited in the present invention. In addition, the pattern formed by the method for producing a cured product pattern according to the embodiment of the present invention can also be used as a mold.

The material constituting the light-transmissive mold used in the present invention is not particularly limited, and examples thereof include glass, quartz, polymethyl methacrylate (PMMA), a light-transmissive resin such as polycarbonate resin, a transparent metal vapor-deposited film, a flexible film such as polydimethylsiloxane, a photo-cured film, and a metal film, among which quartz is preferable.

In the present invention, the material for the non-light-transmissive mold to be used in a case where a light-transmissive substrate is used is not particularly limited and may be any one having a predetermined strength. Specific examples of the non-light-transmissive mold material include, but are not particularly limited to, a ceramic material, a vapor-deposited film, a magnetic film, a reflective film, a metal substrate such as Ni, Cu, Cr, and Fe, and a substrate such as SiC, silicon, silicon nitride, polysilicon, silicon oxide, and amorphous silicon.

In the above-mentioned method for producing a cured product pattern, the mold pressure is preferably 10 atm or lower in a case where imprint lithography is carried out using the curable composition for imprints. By setting the mold pressure to 10 atm or lower, the mold and the substrate are hardly deformed, and thus the patterning accuracy tends to be improved. In addition, it is also preferable from the viewpoint that there is a tendency that the apparatus may be small-sized because the pressure to be given to the mold is low. The mold pressure is preferably selected from a range in which uniformity of mold transfer can be ensured while the residual film of the curable composition for imprints corresponding to the mold convex portion is reduced.

In addition, it is also preferable that the curable composition for imprints and the mold are brought into contact with each other in an atmosphere containing helium gas or condensable gas, or both helium gas and condensable gas.

### Light Irradiation Step

In the light irradiation step, the curable composition for imprints is irradiated with light to form a cured product. The irradiation amount of light irradiation in the light irradiation step may be sufficiently larger than the minimum irradiation amount necessary for curing. The irradiation amount necessary for curing is appropriately determined by examining the consumption of unsaturated bonds in the curable composition for imprints.

The type of light to irradiate with is not particularly defined, and may be, for example, ultraviolet light.

In the imprint lithography applied to the present invention, light irradiation is carried out while keeping the substrate temperature generally at room temperature, where the light irradiation may alternatively be carried out under heating for the purpose of enhancing the reactivity. Light irradiation can also be carried out in vacuo, since a vacuum conditioning prior to the light irradiation is effective for preventing entrainment of air bubbles, for suppressing the reactivity from being reduced due to incorporation of oxygen, and for improving the adhesiveness between the mold and the curable composition for imprints. In the method for producing a cured product pattern, the degree of vacuum (absolute pressure) at the time of light irradiation is preferably in the range from 10⁻¹ Pa to normal pressure.

Upon exposure, the exposure illuminance is preferably in the range of 1 mW/cm² to 500 mW/cm².

In the method for producing a cured product pattern, after curing the film-like curable composition for imprints (pattern forming layer) by light irradiation, a step of applying heat to the cured pattern to cure the pattern may be further included, as necessary. The temperature for heat-curing the curable composition for imprints after light irradiation is preferably 150° C. to 280° C. and more preferably 200° C. to 250° C. The time for applying heat is preferably 5 to 60 minutes and more preferably 15 to 45 minutes.

### Mold Release Step

In the mold release step, the cured product and the mold are separated from each other (FIG. 1(5)). The obtained cured product pattern can be used for various applications as described later.

That is, the present invention discloses a laminate further having a cured product pattern formed from the curable composition for imprints on the surface of the underlayer film. In addition, the film thickness of the pattern forming layer made of the curable composition for imprints used in the embodiment of the present invention is about 0.01 μm to 30 μm, although it varies depending on the intended use.

Further, as will be described later, etching or the like can be carried out.

### Cured Product Pattern and Applications Thereof

As described above, the cured product pattern formed by the method for producing a cured product pattern can be used as a permanent film used for a liquid crystal display (LCD) device or the like, or as an etching resist (lithography mask) for producing a semiconductor element.

In particular, the present invention discloses a method for producing a circuit board, which includes a step of obtaining a cured product pattern by the method for producing a cured product pattern according to the embodiment of the present invention. The method for producing a circuit board according to the embodiment of the present invention may further include a step of etching or ion implantation on a substrate using the cured product pattern obtained by the above-mentioned method for producing a cured product pattern as a mask, and a step of forming an electronic member. The circuit board is preferably a semiconductor element. The present invention discloses a method for producing an electronic device, which further includes a step of obtaining a circuit board by the above-mentioned method for producing a circuit board and a step of connecting the circuit board and a control mechanism for controlling the circuit board.

In addition, in a case where a grid pattern is formed on the glass substrate of the liquid crystal display device using the pattern formed by the above-mentioned method for producing a cured product pattern, it is possible to produce a polarizing plate having a large screen size (for example, 55 inches or more than 60 inches) with low reflection and absorption at low cost. For example, a polarizing plate described in JP2015-132825A and WO2011-132649 can be produced. One inch is 25.4 mm.

The cured product pattern formed in the embodiment of the present invention is also useful as an etching resist (lithography mask) as shown in FIG. 1(6) and (7). In a case where the cured product pattern is used as the etching resist, first, for example, using a silicon substrate (silicon wafer or the like) on which a thin film of SiO₂ or the like is formed as a substrate, for example, a fine cured product pattern of nano-order or micron order is formed on the substrate by the above-mentioned method for producing a cured product pattern. In the present invention, it is particularly advantageous in that a nano-order fine pattern can be formed, and further a pattern having a size of 50 nm or less, particularly 30 nm or less can be formed. The lower limit value of the size of the cured product pattern formed by the above-mentioned method for producing a cured product pattern is not particularly defined, but can be, for example, 1 nm or more.

In addition, the present invention also discloses a method for producing a mold for imprints, which includes a step of obtaining a cured product pattern on a substrate by the method for producing a cured product pattern according to the embodiment of the present invention and a step of etching on the substrate using the obtained cured product pattern.

By etching using an etching gas such as hydrogen fluoride in a case of wet etching or CF₄ in a case of dry etching, a desired cured product pattern can be formed on the substrate. The cured product pattern has particularly good etching resistance against dry etching. That is, the pattern formed by the above-mentioned method for producing a cured product pattern is preferably used as a lithography mask.

Specifically, the pattern formed in the present invention can be preferably used for the production of a recording medium such as a magnetic disc, a light receiving element such as a solid image pickup element, a light emitting element such as a light emitting diode (LED) or an organic electroluminescence (organic EL), an optical device such as a liquid crystal display (LCD) device, an optical component such as a diffraction grating, a relief hologram, an optical waveguide, an optical filter, or a microlens array, a member for flat panel displays such as a thin film transistor, an organic transistor, a color filter, an antireflection film, a polarizing plate, a polarizing element, an optical film, or a pillar material, a nanobio device, an immunoassay chip, a deoxyribonucleic acid (DNA) separation chip, a microreactor, a photonic liquid crystal, a guide pattern for directed self-assembly (DSA) using self-organization of a block copolymer, or the like.

### EXAMPLES

Hereinafter, the present invention will be described in more detail with reference to Examples. The materials, amounts used, ratios, processing details, processing procedures, and the like shown in the following Examples can be changed as appropriate without departing from the spirit of the present invention. Accordingly, the scope of the present invention is not limited to the specific examples shown below.

### Preparation of Composition for Forming Underlayer Film for Imprints

As shown in Tables 2 to 4, individual compounds were blended in (except for the curable composition for imprints shown at the bottom of the table), and then two-stage filtration was carried out with a polytetrafluoroethylene (PTFE) filter having a pore size of 0.1 μm and a PTFE filter having a pore size of 0.003 μm to prepare compositions for forming an underlayer film for imprints (Examples or Comparative Examples). The compounds B-1 to B-35 are the exemplary compounds described above.

### Preparation of Curable Compositions (V-1) to (V-5) for Imprints

As shown in Table 6 below, individual compounds were blended, and 200 mass ppm (0.02% by mass) of 4-hydroxy-2,2,6,6-tetramethylpiperidine-1-oxyl free radical (manufactured by Tokyo Chemical Industry Co., Ltd.) as a polymerization inhibitor was further added with respect to the total amount of polymerizable compounds. The resultant was subjected to filtration with a polytetrafluoroethylene (PTFE) filter having a pore size of 0.1 μm and then filtration with a PTFE filter having a pore size of 0.003 μm to obtain curable compositions (V-1) to (V-5) for imprints.

### Measurement of Surface Tension

The surface tension of the compounds shown in Table 1 was measured by a surface tensiometer CBVP-A3 (manufactured by Kyowa Interface Science Co., Ltd.) at 23° C. using a glass plate. The unit of the surface tension is expressed in mN/m. Two samples were produced for each level and respectively measured three times. A total of 6 arithmetic average values were adopted as evaluation values.

### Measurement of Viscosity

The viscosity of the compounds shown in Table 1 was measured by using an E type rotational viscometer RE85L (manufactured by Toki Sangyo Co., Ltd.) equipped with a standard cone rotor (1°34′×R24), and adjusting a sample cup to a temperature of 23° C. The unit of the viscosity is expressed in mPa·s. For other details regarding the measurement, JIS Z 8803:2011 was conformed to. Two samples were produced for each level and respectively measured three times. A total of 6 arithmetic average values were adopted as evaluation values.

### Ohnishi Parameter

The number of carbon atoms, hydrogen atoms, and oxygen atoms as constituent components was obtained by substituting it into the following formula. In a case where a plurality of compounds were incorporated, an Onishi parameter was calculated from the number of carbon atoms, the number of hydrogen atoms, and the number of oxygen atoms per unit mass of the composition, which were calculated from a mass ratio of each component.

Ohnishi parameter=(sum of the number of carbon atoms, hydrogen atoms, and oxygen atoms)/(the number of carbon atoms−the number of oxygen atoms)

### Preparation of Underlayer Film

### Examples 1 to 20, Examples 22 to 37, Comparative Example 1, and Comparative Example 2

A composition for forming an adhesion layer shown in Example 6 of JP2014-024322A was spin-coated on a silicon wafer and heated using a hot plate at 220° C. for 1 minute to form an adhesion film having a thickness of 5 nm. Then, each of the compositions for forming an underlayer film for imprints shown in the Examples and Comparative Examples was spin-coated on the surface of the adhesion film, and heated for 1 hour using a hot plate at 60° C. to form each of underlayer films having a thickness shown in Table 5.

### Example 21

The composition for forming an underlayer film for imprints shown in the Example 21 was spin-coated on a silicon wafer, and heated for 1 hour using a hot plate at 60° C., the solvent was dried, and thereby an underlayer film having a thickness shown in Table 5 was formed.

### Evaluation of Uniformity in Film Thickness

A film thickness of the surface of the underlayer film obtained above was measured using an ellipsometer (irradiation spot diameter: 30 μm×90 μm). 30 points were measured in the same wafer, uniformity (3σ) in film thickness on the surface of the underlayer film was calculated, and it was evaluated according to the following criteria.

A: 3σ≤1.5

B: 1.5<3σ≤3.0

C: 3.0<3σ

### Evaluation of Wettability of IJ Liquid Droplets

On the surface of each of the underlayer films obtained in the same manner as describe above, the curable composition for imprints, which was one of the curable compositions V-1 to V-4 for imprints shown in Table 6 and of which the temperature was adjusted to 23° C., was ejected at a liquid droplet volume of 6 pL per nozzle using an ink jet printer DMP-2831 (manufactured by FUJIFILM Dimatics Inc.), so that the liquid droplets were applied in a square array at intervals of about 880 μm on the surface of the underlayer film. After the application, the shape of the liquid droplets 3 seconds later was imaged (a size of the captured photo was 1 mm×1 mm), the average diameter of the ink jet (IJ) liquid droplets was measured, and it was evaluated according to the following criteria.

A: average diameter of IJ liquid droplets>400 μm

B: 250 μm<average diameter of IJ liquid droplets≤400 μm

C: 200 μm<average diameter of IJ liquid droplets≤250 μm

D: average diameter of IJ liquid droplets≤200 μm

### Stability in Film Thickness of Underlayer Film (Temporal Stability)

A film thickness (T1) of the underlayer film which was obtained immediately after the production of the film and which was obtained in the same manner as described above was measured. Furthermore, the wafer on which the underlayer film was formed was left at room temperature for 48 hours, a film thickness (T2) was measured again, and it was evaluated according to the following criteria. The film thickness difference (ΔFT=|T1−T2|) between the film thickness immediately after the formation of the underlayer film and the film thickness after 48 hours was confirmed.

The film thickness of the underlayer film was measured with an ellipsometer and an atomic force microscope.

A: ΔFT≤0.5 nm

B: 0.5 nm<ΔFT≤1.0 nm

C: Measurement was not possible (no thin film formed after 48 hours)

TABLE 2

| | Example 1 | Example 2 | Example 3 | Example 4 | Example 5 | Example 6 | Example 7 |
|---|---|---|---|---|---|---|---|
| B-1 (Parts by mass) | 1.0 | 0.5 | 0.3 | 0.1 | | | |
| B-2 (Parts by mass) | | | | | 0.3 | | |
| B-3 (Parts by mass) | | | | | | 0.3 | |
| B-4 (Parts by mass) | | | | | | | 0.3 |
| B-5 (Parts by mass) | | | | | | | |
| B-6 (Parts by mass) | | | | | | | |
| B-7 (Parts by mass) | | | | | | | |
| B-8 (Parts by mass) | | | | | | | |
| B-9 (Parts by mass) | | | | | | | |
| B-10 (Parts by mass) | | | | | | | |
| C-1 (Parts by mass) | | | | | | | |
| PGMEA (Parts by | 90.000 | 99.500 | 99.700 | 99.900 | 99.700 | 99.700 | 99.700 |
| mass) | | | | | | | |
| PGME (Parts by | | | | | | | |
| mass) | | | | | | | |
| Curable composition | V-1 | V-3 | V-1 | V-2 | V-4 | V-1 | V-3 |
| for imprint | | | | | | | |

| | Example 8 | Example 9 | Example 10 | Example 11 | Example 12 | Example 13 |
|---|---|---|---|---|---|---|
| B-1 (Parts by mass) | | | | | | |
| B-2 (Parts by mass) | | | | | | |
| B-3 (Parts by mass) | | | | | | |
| B-4 (Parts by mass) | | | | | | |
| B-5 (Parts by mass) | 0.3 | | | | | |
| B-6 (Parts by mass) | | 0.3 | | | | |
| B-7 (Parts by mass) | | | 0.3 | | | |
| B-8 (Parts by mass) | | | | 0.3 | | |
| B-9 (Parts by mass) | | | | | 0.3 | |
| B-10 (Parts by mass) | | | | | | 0.295 |
| C-1 (Parts by mass) | | | | | | 0.005 |
| PGMEA (Parts by | 99.700 | 99.700 | 99.700 | 99.700 | 99.700 | 99.700 |
| mass) | | | | | | |
| PGME (Parts by | | | | | | |
| mass) | | | | | | |
| Curable composition | V-2 | V-3 | V-1 | V-2 | V-1 | V-4 |
| for imprint | | | | | | |

TABLE 3

| | Example 14 | Example 15 | Example 16 | Example 17 | Example 18 | Example 19 | Example 20 |
|---|---|---|---|---|---|---|---|
| B-1 (Parts by mass) | | | | | | | |
| B-11 (Parts by mass) | 0.3 | | | | | | |
| B-12 (Parts by mass) | | 0.3 | | | | | |
| B-13 (Parts by mass) | | | 0.3 | | | | |
| B-14 (Parts by mass) | | | | 0.3 | | | |
| B-15 (Parts by mass) | | | | | 0.3 | | |
| B-16 (Parts by mass) | | | | | | 0.3 | |
| B-17 (Parts by mass) | | | | | | | 0.3 |
| B-18 (Parts by mass) | | | | | | | |
| B-19 (Parts by mass) | | | | | | | |
| B-20 (Parts by mass) | | | | | | | |
| B-21 (Parts by mass) | | | | | | | |
| B-22 (Parts by mass) | | | | | | | |
| B-23 (Parts by mass) | | | | | | | |
| B-24 (Parts by mass) | | | | | | | |
| B-25 (Parts by mass) | | | | | | | |
| B-26 (Parts by mass) | | | | | | | |
| B-27 (Parts by mass) | | | | | | | |
| B-34 (Parts by mass) | | | | | | | |
| B-35 (Parts by mass) | | | | | | | |
| B-36 (Parts by mass) | | | | | | | |
| C-1 (Parts by mass) | | | | | | | |
| PGMEA (Parts by | 99.700 | 99.700 | 99.700 | 99.700 | 99.700 | 99.700 | 99.700 |
| mass) | | | | | | | |
| PGME (Parts by | | | | | | | |
| mass) | | | | | | | |
| Curable composition | V-2 | V-1 | V-2 | V-1 | V-3 | V-2 | V-1 |
| for imprint | | | | | | | |
| | Example 21 | Example 22 | Example 23 | Example 24 | Example 25 | Example 26 | Example 27 |
| B-1 (Parts by mass) | | | 0.1 | | | | |
| B-11 (Parts by mass) | | | | | | | |
| B-12 (Parts by mass) | | | | | | | |
| B-13 (Parts by mass) | | | | | | | 0.1 |
| B-14 (Parts by mass) | | | | | | | |
| B-15 (Parts by mass) | | | | | | | |
| B-16 (Parts by mass) | | | | | | | |
| B-17 (Parts by mass) | | | | | | | |
| B-18 (Parts by mass) | 0.199 | | | | | | |
| B-19 (Parts by mass) | 0.1 | | | | | | |
| B-20 (Parts by mass) | | 0.3 | | | | | |
| B-21 (Parts by mass) | | | 0.1 | | | | |
| B-22 (Parts by mass) | | | 0.1 | | | | |
| B-23 (Parts by mass) | | | | 0.3 | | | |
| B-24 (Parts by mass) | | | | | 0.1 | | |
| B-25 (Parts by mass) | | | | | 0.2 | | |
| B-26 (Parts by mass) | | | | | | 0.3 | |
| B-27 (Parts by mass) | | | | | | | 0.1 |
| B-34 (Parts by mass) | | | | | | | 0.1 |
| B-35 (Parts by mass) | | | | | | | |
| B-36 (Parts by mass) | | | | | | | |
| C-1 (Parts by mass) | 0.001 | | | | | | |
| PGMEA (Parts by | | 99.700 | 99.700 | 99.700 | 99.700 | 99.700 | 99.700 |
| mass) | | | | | | | |
| PGME (Parts by | 99.700 | | | | | | |
| mass) | | | | | | | |
| Curable composition | V-3 | V-1 | V-3 | V-3 | V-1 | V-3 | V-3 |
| for imprint | | | | | | | |

TABLE 4

| | Example | Example | Example | Example | Example | Example | Example | Example |
|---|---|---|---|---|---|---|---|---|
| | 28 | 29 | 30 | 31 | 32 | 33 | 34 | 35 |
| B-1 (Parts by mass) | | | | | | | | |
| B-2 (Parts by mass) | | | | | | | | |
| B-3 (Parts by mass) | | | | | | | | |
| B-4 (Parts by mass) | | | | | | | | |
| B-5 (Parts by mass) | 0.2 | | | | | | | |
| B-28 (Parts by mass) | 0.1 | | | | | | | |
| B-29 (Parts by mass) | | 0.3 | | | | | | |
| B-30 (Parts by mass) | | | 0.3 | | | | | |
| B-31 (Parts by mass) | | | | 0.3 | | | | |
| B-32 (Parts by mass) | | | | | 0.3 | | | |
| B-33 (Parts by mass) | | | | | | 0.3 | | |
| B-34 (Parts by mass) | | | | | | | 0.3 | |
| B-35 (Parts by mass) | | | | | | | | 0.3 |
| B-36 (Parts by mass) | | | | | | | | |
| C-1 (Parts by mass) | | | | | | | | |
| H-1 (Parts by mass) | | | | | | | | |
| H-2 (Parts by mass) | | | | | | | | |
| H-3 (Parts by mass) | | | | | | | | |
| H-4 (Parts by mass) | | | | | | | | |
| PGMEA (Parts by | 99.700 | 99.700 | 99.700 | 99.700 | 99.700 | 99.700 | 99.700 | 99.700 |
| mass) | | | | | | | | |
| PGME (Parts by | | | | | | | | |
| mass) | | | | | | | | |
| Curable composition | V-1 | V-2 | V-1 | V-3 | V-3 | V-1 | V-4 | V-2 |
| for imprint | | | | | | | | |

| | Example | Example | Comparative | Comparative | Comparative | Comparative |
|---|---|---|---|---|---|---|
| | 36 | 37 | Example 1 | Example 2 | Example 3 | Example 4 |
| B-1 (Parts by mass) | 0.5 | 1.0 | | | | |
| B-2 (Parts by mass) | | | | | | |
| B-3 (Parts by mass) | | | | | | |
| B-4 (Parts by mass) | | | | | | |
| B-5 (Parts by mass) | | | | | | |
| B-28 (Parts by mass) | | | | | | |
| B-29 (Parts by mass) | | | | | | |
| B-30 (Parts by mass) | | | | | | |
| B-31 (Parts by mass) | | | | | | |
| B-32 (Parts by mass) | | | | | | |
| B-33 (Parts by mass) | | | | | | |
| B-34 (Parts by mass) | | | | | | |
| B-35 (Parts by mass) | | | | | | |
| B-36 (Parts by mass) | 0.5 | | | | | |
| C-1 (Parts by mass) | | | | | | |
| H-1 (Parts by mass) | | | 0.300 | | | |
| H-2 (Parts by mass) | | | | 0.300 | | |
| H-3 (Parts by mass) | | | | | 0.300 | |
| H-4 (Parts by mass) | | | | | | 0.500 |
| PGMEA (Parts by | 99.000 | 99.000 | 99.700 | 99.700 | 99.700 | 99.700 |
| mass) | | | | | | |
| PGME (Parts by | | | | | | |
| mass) | | | | | | |
| Curable composition | V-1 | V-5 | V-3 | V-3 | V-3 | V-3 |
| for imprint | | | | | | |

The viscosity of the composition of Example 36 at 23° C. was 1.2 mPa · s.

TABLE 5

| | Film | Uniformity | | |
|---|---|---|---|---|
| | thickness | in film | Wetta- | Temporal |
| | (nm) | thickness | bility | stability |
| Example 1 | 25 | A | A | A |
| Example 2 | 14 | A | A | A |
| Example 3 | 8 | A | A | A |
| Example 4 | 3 | A | A | A |
| Example 5 | 8 | A | A | A |
| Example 6 | 8 | A | A | A |
| Example 7 | 8 | A | A | A |
| Example 8 | 8 | B | A | B |
| Example 9 | 8 | B | A | B |
| Example 10 | 8 | A | A | A |
| Example 11 | 8 | A | A | A |
| Example 12 | 8 | A | A | A |
| Example 13 | 8 | A | A | A |
| Example 14 | 8 | A | A | A |
| Example 15 | 8 | A | A | A |
| Example 16 | 8 | A | A | A |
| Example 17 | 8 | A | A | A |
| Example 18 | 8 | A | A | A |
| Example 19 | 8 | A | B | A |
| Example 20 | 8 | A | A | A |
| Example 21 | 8 | A | A | A |
| Example 22 | 8 | A | B | A |
| Example 23 | 8 | A | A | A |
| Example 24 | 8 | A | A | A |
| Example 25 | 8 | A | A | A |
| Example 26 | 8 | A | A | A |
| Example 27 | 8 | B | A | B |
| Example 28 | 8 | A | A | A |
| Example 29 | 8 | A | A | A |
| Example 30 | 8 | A | B | A |
| Example 31 | 8 | B | A | B |
| Example 32 | 8 | B | B | B |
| Example 33 | 8 | B | A | B |
| Example 34 | 8 | B | A | B |
| Example 35 | 8 | A | A | A |
| Example 36 | 25 | B | B | B |
| Example 37 | 25 | A | C | A |
| Comparative | 8 | C | A | C |
| Example1 | | | | |
| Comparative | 8 | A | D | A |
| Example2 | | | | |
| Comparative | 8 | A | D | A |
| Example3 | | | | |
| Comparative | 9 | A | D | A |
| Example4 | | | | |

TABLE 6

| | Boiling | | | | | |
|---|---|---|---|---|---|---|
| | point (° C.) | V-1 | V-2 | V-3 | V-4 | V-5 |
| 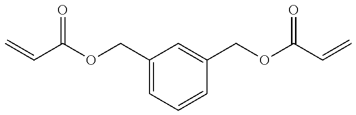 [SMILES: C=CC(=O)OCc1cccc(COC(=O)C=C)c1] | 388.23 | 60 | 63 | 50 | | |
| 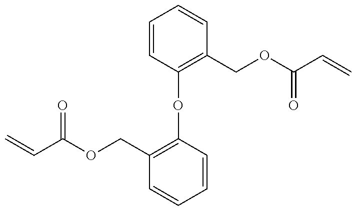 [SMILES: C=CC(=O)OCc1ccccc1Oc1ccccc1COC(=O)C=C] | 579.59 | 13 | | | | |
| 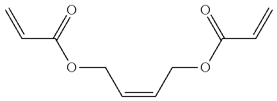 | 269.21 | | 22 | | | |
| 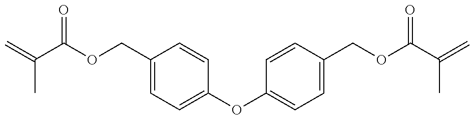 [SMILES: C=C(C)C(=O)OCc1ccc(Oc2ccc(COC(=O)C(=C)C)cc2)cc1] | 579.59 | | | | 46 | |
| 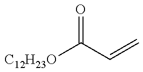 | 324.55 | 20 | 6 | | | |
| 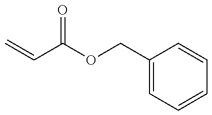 | 236.83 | | | 33 | 35 | |
| 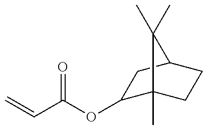 | 287.68 | | | 10 | 10 | 70 |
| 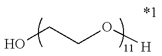 | | 2 | 2 | 2 | 2 | 2 |
| 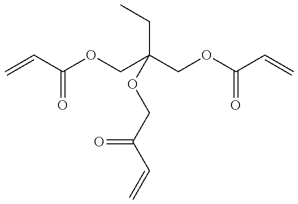 [SMILES: C=CC(=O)COC(CC)(COC(=O)C=C)COC(=O)C=C] | | | 2 | 2 | 2 | 22 |
| 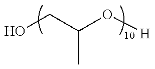 | | 3 | | | | |
| 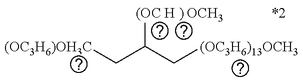 | | | 3 | | | |
| 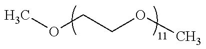 | | | | 1 | | 3 |
| Fluorine-based surfactant | | | | | 3 | |
| (Capstone FS-3100) | | | | | | |
| IRGACURE 819 | | 2 | | 1.5 | 1.99 | 2.5 |
| (manufactured by BASF Corporation) | | | | | | |
| IRGACURE OXE-01 | | | 2 | | | |
| (manufactured by BASF Corporation) | | | | | | |
| IRGACURE 1173 | | | | 0.49 | | 0.5 |
| (manufactured by BASF Corporation) | | | | | | |
| BHT | | | | 0.01 | | |
| (manufactured by Tokyo Chemical Industry Co., Ltd.) | | | | | | |
| 4-OH-TEMPO | | | | | 0.01 | |
| (manufactured by Tokyo Chemical Industry Co., Ltd.) | | | | | | |
| Viscosity at 23° C. (mPa · s) | 8 | 7 | 7 | <6 | 13 | |
| Surface tension at 23° C. (mN/m) | 33.0 | 34.0 | 35.0 | 33.0 | 38.0 | |
| Ohnishi parameter | 3.5 | 3.5 | 3.0 | 3.5 | 3.2 | |

*1: The surface tension at 23° C. is 44 mN/m.

PGMEA: Propylene glycol monomethyl ether acetate

PGME Propylene glycol monomethyl ether

### Polyfunctional (meth)acrylate for Comparison

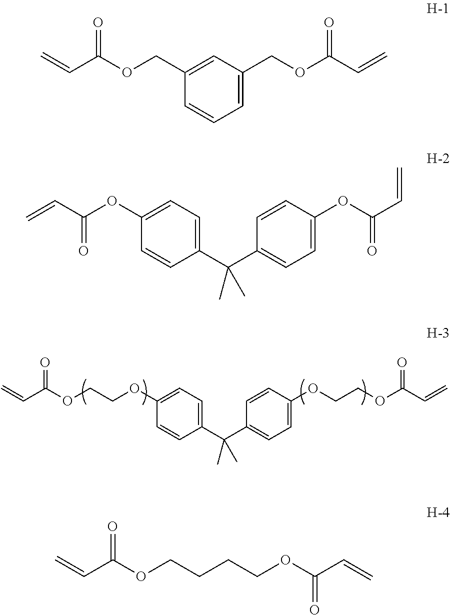

### C-1: Polymerization Initiator

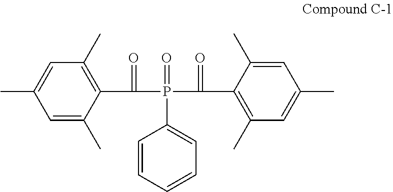

The boiling point in Table 6 is a value at 1013.25 hPa. The amount of each component in Tables 2 to 4 and 6 is a mass ratio. Structural formula*2 in Table 6 is a mixture, and m+n+1 is 10 on average.

As it became clear based on the above results, by using the composition for forming an underlayer film for imprints which includes the specific polyfunctional (meth)acrylate according to the present invention, it can be seen that uniformity in film thickness becomes excellent, high wettability is shown, favorable temporal stability of a film is shown (Example). On the other hand, it can be seen that the composition for forming an underlayer film for imprints formed of polyfunctional (meth)acrylate having an excessively low viscosity has inferior uniformity in film thickness and temporal stability of a film (Comparative Example 1). Moreover, it can be seen that the composition for forming an underlayer film for imprints using polyfunctional (meth)acrylate that is a solid at 23° C. has inferior wettability (Comparative Example 2).

### EXPLANATION OF REFERENCES

1: substrate

2: underlayer film

3: curable composition for imprints

4: mold

21: underlayer film

22: curable composition for imprints

What is claimed is:

1. A composition for forming an underlayer film for imprints, comprising:
a polyfunctional (meth)acrylate that includes at least one aromatic ring or aromatic heterocyclic ring; and
a solvent,
wherein a viscosity of the polyfunctional (meth)acrylate at 23° C. is 11 to 600 mPa·s, and
a molecular weight of the polyfunctional (meth)acrylate is 200 or more.

2. The composition for forming an underlayer film for imprints according to claim 1,
wherein the at least one ring included in the polyfunctional (meth)acrylate satisfies at least one of the following conditions (a) to (d):
(a) the at least one ring includes at least one 5-membered ring or 6-membered ring;
(b) the at least one ring includes a heterocyclic ring having at least one of a nitrogen atom, an oxygen atom, or a sulfur atom as a hetero atom;
(c) the at least one ring includes a fused ring; and
(d) the at least one ring includes two or more rings selected from aromatic rings and aromatic heterocyclic rings.

3. The composition for forming an underlayer film for imprints according to claim 1, wherein a boiling point of the polyfunctional (meth)acrylate is 370° C. or higher.

4. The composition for forming an underlayer film for imprints according to claim 1, wherein an Ohnishi parameter of the polyfunctional (meth)acrylate is 2.0 to 4.5; where, the Ohnishi parameter is (a sum of the number of carbon atoms, hydrogen atoms, and oxygen atoms)/(the number of carbon atoms−the number of oxygen atoms) for atoms constituting each compound.

5. The composition for forming an underlayer film for imprints according to claim 1, wherein the polyfunctional (meth)acrylate is represented by Formula (1); 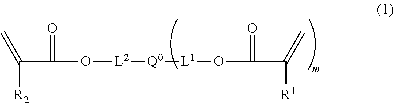
in the formula, Q⁰ represents at least one aromatic-ring-containing group or aromatic-heterocyclic-ring-containing group, R¹ and R² each independently represent a hydrogen atom or a methyl group, L¹ and L² each independently represent a single bond or a linking group, and m represents an integer of 1 to 4.

6. The composition for forming an underlayer film for imprints according to claim 1, wherein a content of the polyfunctional (meth)acrylate is 0.01% by mass to 1.0% by mass.

7. A kit comprising:
the composition for forming an underlayer film for imprints according to claim 1; and
a curable composition for imprints.

8. The kit according to claim 7, wherein the curable composition for imprints includes a polyfunctional (meth)acrylate, and the polyfunctional (meth)acrylate in the curable composition for imprints includes at least one aromatic ring or aromatic heterocyclic ring.

9. The kit according to claim 7, wherein an absolute value of a difference between a viscosity of the polyfunctional (meth)acrylate used in the composition for forming an underlayer film for imprints at 23° C. and a viscosity of the curable composition for imprints at 23° C. is 500 mPa·s or less.

10. A composition for forming an underlayer film for imprints, the composition included in the kit according to claim 7.

11. A curable composition for imprints, the curable composition used for the kit according to claim 7.

12. A laminate formed from the kit according to claim 7, the laminate comprising:
an underlayer film formed from the composition for forming an underlayer film for imprints; and
a pattern forming layer formed from the curable composition for imprints and positioned on a surface of the underlayer film.

13. A method for producing a laminate using the kit according to claim 7, the method comprising:
applying a curable composition for imprints on a surface of an underlayer film formed from a composition for forming an underlayer film for imprints.

14. The method for producing a laminate according to claim 13, wherein the curable composition for imprints is applied on the surface of the underlayer film by an ink jet method.

15. The method for producing a laminate according to claim 13, further comprising:
applying the composition for forming an underlayer film for imprints in a layer form on a substrate; and
heating the composition for forming an underlayer film for imprints applied in a layer form at 40° C. to 100° C.

16. A method for producing a cured product pattern, using the kit according to claim 7, the method comprising:
applying a composition for forming an underlayer film for imprints on a substrate to form an underlayer film;
applying a curable composition for imprints on a surface of the underlayer film;
bringing the curable composition for imprints into contact with a mold having a pattern for transferring a pattern shape;
irradiating the curable composition for imprints with light to form a cured product; and
separating the cured product and the mold from each other.

17. A method for producing a circuit board, comprising:
obtaining a cured product pattern by the production method according to claim 16.
